(19) United States
(12) Patent Application Publication
(10) Pub. No.: US 2025/0040263 A1
(43) Pub. Date: Jan. 30, 2025

(54) SINGLE PHOTON AVALANCHE DIODE, ELECTRONIC DEVICE, AND LiDAR DEVICE

(71) Applicant: TRUPIXEL INC., Daejeon (KR)

(72) Inventor: Myung-Jae LEE, Seoul (KR)

(21) Appl. No.: 18/784,621

(22) Filed: Jul. 25, 2024

(30) Foreign Application Priority Data
Jul. 25, 2023 (KR) 10-2023-0096675
Oct. 14, 2023 (KR) 10-2023-0137219

(51) Int. Cl. H01L 31/107; G01S 7/481; H01L 31/0352

(52) U.S. Cl. CPC H01L 31/107; G01S 7/4811; H01L 31/0352

(57) ABSTRACT

Disclosed is a single photon avalanche diode comprises a first well having a first conductivity type, a heavily doped region provided on the first well, a guard ring surrounding the heavily doped region, and a second region formed between the first well and the heavily doped region and configured to multiply charge carriers. The heavily doped region and the guard ring have a second conductivity type different from the first conductivity type. The second region extends onto a boundary between a lower portion of the guard ring and the first well.

### CROSS-REFERENCE TO RELATED APPLICATIONS

The application claims benefit of priority under 35 U.S.C. § 119 to Korean Patent Application Nos. 10-2023-0096675 filed on Jul. 25, 2023, and 10-2023-0137219 filed on Oct. 14, 2023, in the Korean Intellectual Property Office, the disclosures of which are incorporated by reference herein in their entireties.

### BACKGROUND

The present disclosure relates generally to an image sensor and a method of manufacturing the image sensor.

An avalanche photodiode (APD) is a solid-state photodetector in which a high bias voltage is applied to the p-n junction to provide a high gain from avalanche multiplication. When the incident photon with energy higher than the band gap in the semiconductor reaches the photodiode, electron-hole pairs (EHPs) are generated. The high electric field accelerates the photo-generated electrons quickly toward an anode, and the additional electron-hole pairs are generated in succession by the impact ionization by such accelerated electrons, and then those of the electrons accelerate to the anode. Similarly, the high electric field accelerates the photo-generated holes quickly towards a cathode, and then causes the same phenomenon. This process repeats the process leading to the avalanche multiplication of the photo-generated electrons and holes. Thus, the APD is a semiconductor-based device that operates similarly to photomultiplier tubes. The linear-mode APD is an effective amplifier that can control the bias voltage to set the gain and obtain tens of to thousands of gains in linear mode.

A single photon avalanche diode (SPAD) is an APD in which the p-n junction is biased more than breakdown voltage to operate in the Geiger mode. An incident single photon can trigger the avalanche phenomena, generate a very large current, and as a result, obtain a pulse signal that can be easily measured with a quenching resistor or a circuit. That is, the SPAD operates as a device that generates a large pulse signal compared to the linear-mode APD. After triggering the avalanche, the quenching resistor or the circuit is used to reduce the bias voltage with the breakdown voltage below the breakdown voltage. Once the avalanche process is quenched, the bias voltage is increased again over the breakdown voltage so that the SPAD is reset for the detection of another photon.

The SPADs can be configured with the quenching resistor or the circuit as well as a recharge circuit, a memory, a gate circuit, a counter, and a time-digital converter, as the like. SPAD pixels can be easily configured to arrays, since the SPAD pixels consist of semiconductors.

### SUMMARY

Embodiments of the present disclosure provide single photon avalanche diodes, electronic devices, and lidar devices with improved fill factor and efficiency.

According to example embodiments, a single photon avalanche diode comprises a first well having a first conductivity type, a heavily doped region provided on the first well, a guard ring surrounding the heavily doped region, and a second region formed between the first well and the heavily doped region and configured to multiply charge carriers. The heavily doped region and the guard ring have a second conductivity type different from the first conductivity type. The second region extends onto a boundary between a lower portion of the guard ring and the first well.

According to further aspects of the invention, from a plan view, the second region overlaps the guard ring.

According to further aspects of the invention, the second region has an electric field of 3×10⁵ V/cm or more.

According to further aspects of the invention, the single photon avalanche diode further comprises a first region formed between the first well and the second region and configured to transport the charge carriers to the second region. The first region has an electric field less than 3×10⁵ V/cm.

According to further aspects of the invention, the first region extends along a side of the guard ring disposed opposite the heavily doped region.

According to further aspects of the invention, the single photon avalanche diode further comprises a relief region surrounding the guard ring, and a contact region provided on the relief region. The first region extends between the relief region and the guard ring.

According to further aspects of the invention, the single photon avalanche diode further comprises a device isolation pattern surrounding the relief region.

According to further aspects of the invention, the second region extends onto a bottom surface of the guard ring.

According to further aspects of the invention, the single photon avalanche diode, further comprises a contact region surrounding the guard ring, and a first insulating pattern provided between the contact region and the guard ring.

According to further aspects of the invention, the single photon avalanche diode of claim 1, further comprises a second insulating pattern provided on the guard ring.

According to further aspects of the invention, the single photon avalanche diode, further comprises a lightly doped region provided between the heavily doped region and the guard ring and between the heavily doped region and the first well. The lightly doped region has the second conductivity type and a lower doping concentration than a doping concentration of the heavily doped region.

According to further aspects of the invention, the single photon avalanche diode, further comprises a second well provided between the heavily doped region and the first well. The second well has a different conductivity type and a different doping concentration with the first well.

According to further aspects of the invention, the second region extends along boundaries between the second well and the heavily doped region and between the second well and the guard ring.

According to further aspects of the invention, the single photon avalanche diode of claim 1, further comprises a third well provided between the heavily doped region and the first well. The third well has the second conductivity type. The doping concentration of the third well is lower than a doping concentration of the heavily doped region, but higher than a doping concentration of the guard ring.

According to further aspects of the invention, the second region extends along a boundary between the first well and the third well.

According to further aspects of the invention, the single photon avalanche diode, further comprises a virtual guard ring formed between the guard ring and the first well. The virtual guard ring is configured to alleviate a concentration of electric field in the second region.

According to example embodiments, an electronic device comprises a single photon avalanche diode. The single photon avalanche diode includes a first well having a first conductivity type, a heavily doped region provided on the first well, a guard ring surrounding the heavily doped region, and a second region formed between the first well and the heavily doped region and configured to multiply charge carriers. The heavily doped region and the guard ring have a second conductivity type different from the first conductivity type. The second region extends onto a boundary between a lower portion of the guard ring and the first well.

According to further aspects of the invention, the electronic device further comprises a first region formed between the first well and the second region and configured to transport the charge carriers to the second region.

According to example embodiments, a LiDAR device comprises an electronic device including a single photon avalanche diode. The single photon avalanche diode includes a first well having a first conductivity type, a heavily doped region provided on the first well, a guard ring surrounding the heavily doped region, and a second region formed between the first well and the heavily doped region and configured to multiply charge carriers. The heavily doped region and the guard ring have a second conductivity type different from the first conductivity type. The second region extends onto an interface between a lower portion of the guard ring and the first well.

According to further aspects of the invention, the LiDAR device further comprises a first region formed between the first well and the second region and configured to transport the charge carriers to the second region.

Additional aspects will be set forth in part in the description which follows and, in part, will be apparent from the description, or may be learned by practice of the presented embodiments.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a plan view of a single photon avalanche diode according to example embodiments.

FIG. 2 is a cross-sectional view corresponding to line A-A′ of the single photon avalanche diode of FIG. 1.

FIG. 3 is a plan view of the single photon avalanche diode of FIG. 2 according to example embodiments.

FIG. 4 is a plan view of the single photon avalanche diode of FIG. 2 according to example embodiments.

FIG. 5 is a plan view of the single photon avalanche diode of FIG. 2 according to example embodiments.

FIG. 6 is a plan view of the single photon avalanche diode of FIG. 2 according to example embodiments.

FIG. 7 is a plan view of the single photon avalanche diode of FIG. 2 according to example embodiments.

FIG. 8 is a plan view of the single photon avalanche diode of FIG. 2 according to example embodiments.

FIG. 9 is a plan view of a single photon avalanche diode according to example embodiments.

FIG. 10 is a cross-sectional view corresponding to line B-B′ of the single photon avalanche diode of FIG. 9.

FIG. 11 is a plan view of a single photon avalanche diode according to example embodiments.

FIG. 12 is a cross-sectional view corresponding to line C-C′ of the single photon avalanche diode of FIG. 11.

FIG. 13 is a plan view of a single photon avalanche diode according to example embodiments.

FIG. 14 is a cross-sectional view corresponding to line D-D′ of the single photon avalanche diode of FIG. 13.

FIG. 15 is a plan view of a single photon avalanche diode according to example embodiments.

FIG. 16 is a cross-sectional view corresponding to line E-E′ of the single photon avalanche diode of FIG. 15.

FIG. 17 is a plan view of a single photon avalanche diode according to example embodiments.

FIG. 18 is a cross-sectional view corresponding to line F-F′ of the single photon avalanche diode of FIG. 17.

FIG. 19 is a cross-sectional view corresponding to line A-A′ of the single photon avalanche diode of FIG. 1.

FIG. 20 is a cross-sectional view corresponding to line A-A′ of the single photon avalanche diode of FIG. 1.

FIG. 21 is a plan view of a single photon avalanche diode according to example embodiments.

FIG. 22 is a cross-sectional view corresponding to line G-G′ of the single photon avalanche diode of FIG. 21.

FIG. 23 is a cross-sectional view of a single photon detector according to example embodiments.

FIG. 24 is a cross-sectional view of a single photon detector according to example embodiments.

FIG. 25 is a cross-sectional view of a single photon detector according to example embodiments.

FIG. 26 is a plan view of the first diffraction pattern of FIG. 25.

FIG. 27 is a cross-sectional view of a single photon detector according to example embodiments.

FIG. 28 is a cross-sectional view of a single photon detector according to example embodiments.

FIG. 29 is a plan view of a single photon detector array according to example embodiments.

FIG. 30 is a cross-sectional view corresponding to line H-H′ of FIG. 29.

FIG. 31 is a plan view of the output pattern, the bias pattern, and the shield pattern of FIG. 29.

FIG. 32 is a cross-sectional view corresponding to line H-H′ of FIG. 29.

FIG. 33 is a cross-sectional view corresponding to line H-H′ of FIG. 29.

FIG. 34 is a cross-sectional view corresponding to line H-H′ of FIG. 29.

FIG. 35 is a cross-sectional view corresponding to line H-H′ of FIG. 29.

FIG. 36 is a cross-sectional view corresponding to line H-H′ of FIG. 29.

FIG. 37 is a cross-sectional view corresponding to line H-H′ of FIG. 29.

FIG. 38 is a cross-sectional view corresponding to line H-H′ of FIG. 29.

FIG. 39 is a cross-sectional view corresponding to line H-H′ of FIG. 29.

FIG. 40 is a block diagram for describing an electronic device according to example embodiments.

FIGS. 41 and 42 are conceptual diagrams illustrating cases in which a LiDAR device according to example embodiments is applied to a vehicle.

### DETAILED DESCRIPTION

Hereinafter, some example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are some example embodiments, and thus, the present disclosure is not limited thereto, and may be realized in various other forms. Some example embodiments provided in the following description is not excluded from being associated with one or more features of some other example embodiments also provided herein or not provided herein but consistent with the present disclosure. It will be also understood that, even if a certain step or operation of manufacturing an apparatus or structure is described later than another step or operation, the step or operation may be performed later than the other step or operation unless the other step or operation is described as being performed after the step or operation.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

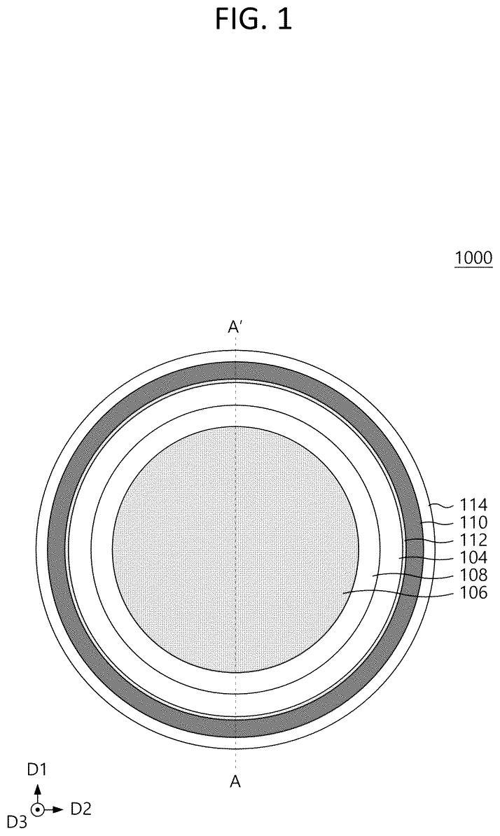

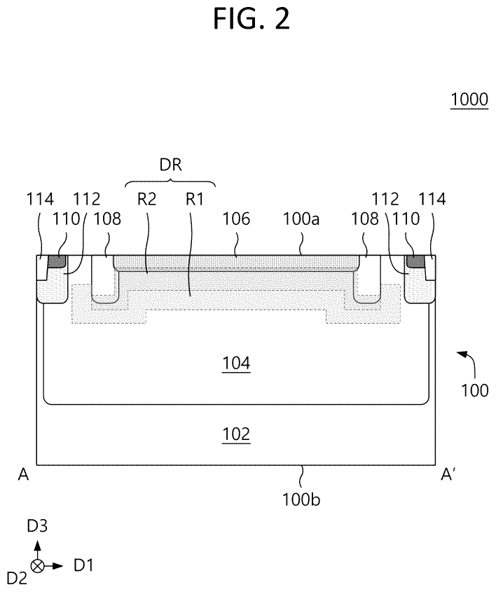

FIG. 1 is a plan view of a single photon avalanche diode according to example embodiments. FIG. 2 is a cross-sectional view corresponding to line A-A′ of the single photon avalanche diode of FIG. 1.

Referring to FIGS. 1 and 2, a single photon avalanche diode 1000 may be provided. The single photon avalanche diode 1000 includes a first well 104, a heavily doped region 106, a guard ring 108, a contact region 110, a relief region 112, and a device isolation pattern 114 formed on a semiconductor substrate 100. The semiconductor substrate 100 may be an epi layer formed by an epitaxial growth process. For example, the semiconductor substrate 100 may be a silicon substrate. The semiconductor substrate 100 may include a front side 100a and a back side 100b that face each other. The front side 100a may be a side surface where several semiconductor processes are performed when manufacturing the single photon avalanche diode 1000, and the back side 100b may be a side surface disposed opposite to the front side 100a. The front side 100a and the back side 100b may be extended along a first direction D1 and a second direction D2. A direction from the back side 100b to the front side 100a may be a third direction D3. For example, the first well 104, the heavily doped region 106, the guard ring 108, the contact region 110, and the relief region 112 may be formed by implanting impurities into the semiconductor substrate 100. A remaining region of the semiconductor substrate 100 excluding the first well 104, the heavily doped region 106, the guard ring 108, the contact region 110, and the relief region 112 is referred to as a substrate region 102.

A conductivity type of the substrate region 102 may be n-type or p-type. When the conductivity type of the substrate region 102 is n-type, the substrate region 102 may include a group 5 element (e.g., phosphorus (P), arsenic (As), antimony (Sb), etc.), a group 6 element, or a group 7 element as an impurity. Hereinafter, the region where the conductivity type is n-type may include a group 5, 6, or 7 element as an impurity (hereinafter, referred to as a first impurity). When the conductivity type of the substrate region 102 is p-type, the substrate region 102 may include a group 3 element (e.g., boron (B), aluminum (Al), gallium (Ga), indium (In), etc.) or a group 2 element as an impurity. Hereinafter, the region where the conductivity type is p-type may include a group 3 or 2 element as an impurity (hereinafter, referred to as a second impurity). For example, a doping concentration of the substrate region 102 may be 1×10¹⁴ to 1×10¹⁹ cm⁻³. The semiconductor substrate 100 may be an epi layer formed by an epitaxial growth process.

The first well 104 may be provided on the substrate region 102. The first well 104 may directly contact the substrate region 102. The first well 104 may have a first conductivity type. For example, a doping concentration of the first well 104 may be 1×10¹⁵ to 1×10¹⁸ cm⁻³. In example embodiments, the first well 104 may have the uniform doping concentration. In example embodiments, the doping concentration of the first well 104 may be decreased as it approaches the front side 100a. Although a top surface of the first well 104 is shown to be located at substantially the same height as the front side 100a, this is not limited. In another embodiments, the top surface of the first well 104 may be disposed below the front side 100a.

The heavily doped region 106 may be provided on the first well 104. The heavily doped region 106 may contact the top surface of the first well 104. The heavily doped region 106 may be exposed between the guard rings 108, which will be described later. The heavily doped region 106 may have a second conductivity type different from the first conductivity type. As the first well 104 and the heavily doped region 106 have different conductivity types, a depletion region DR may be formed at and around a boundary between the first well 104 and the heavily doped region 106. When the first conductivity type is n-type or p-type, the second conductivity type may be p-type or n-type, respectively. For example, a doping concentration of the heavily doped region 106 may be 1×10¹⁵ to 2×10²⁰ cm⁻³. The heavily doped region 106 may be electrically connected to at least one of an external power source, a DC-to-DC converter, and other power management integrated circuits. In example embodiments, the heavily doped region 106 may be electrically connected to at least one of a quenching resistor (or a quenching circuit) and another pixel circuit. The quenching resistor (or the quenching circuit) can stop the avalanche effect and allow the single photon avalanche diode 1000 to detect another photon. Other pixel circuits may include, for example, a reset or a recharge circuit, a memory, an amplification circuit, a counter, a gate circuit, a time-to-digital converter, and the like. Other pixel circuits may transmit signals to the single photon avalanche diode 1000 or receive signals from the single photon avalanche diode 1000.

The guard ring 108 may surround the heavily doped region 106. The guard ring 108 may be provided on a side surface of the heavily doped region 106. For example, the guard ring 108 may have a ring shape extending along the side surface of the heavily doped region 106. The guard ring 108 may directly contact the heavily doped region 106. The guard ring 108 may be configured to surround the end of the heavily doped region 106. For example, the guard ring 108 may contact side and bottom surfaces of the ends of the heavily doped region 106. In another embodiments, the guard ring 108 may be configured to contact only the side surface of the heavily doped region 106. In another embodiments, the guard ring 108 may be spaced apart from the heavily doped region 106. A top surface of the guard ring 108 may be disposed at substantially the same height as a top surface of the heavily doped region 106. The guard ring 108 may have the second conductivity type. A doping concentration of the guard ring 108 may be determined so that a second region R2 is formed at and around the boundary between a lower region of the guard ring 108 and the first well 104. For example, the doping concentration of the guard ring 108 may be determined so that an electric field formed by the lower region of the guard ring 108 and the first well 104 immediately adjacent thereto has a magnitude of 3×10⁵ V/cm or more. In example embodiments, the doping concentration of the guard ring 108 may be substantially the same as or lower than the doping concentration of the heavily doped region 106. For example, the doping concentration of the guard ring 108 may be 1×10¹⁵ to 5×10¹⁷ cm⁻³. The guard ring 108 can improve the breakdown characteristics of the single photon avalanche diode 1000. Specifically, the guard ring 108 can alleviate a concentration of the electric field in a portion of the depletion region DR and prevent a premature breakdown phenomenon. The premature breakdown phenomenon occurs when breakdown occurs first in a portion of the depletion region DR before the electric field of sufficient magnitude is applied throughout the depletion region DR. The premature breakdown phenomenon occurs as the electric field is concentrated in the portion of the depletion region DR. A depth of the guard ring 108 can be determined as needed. For example, the guard ring 108 may be formed deeper or shallower than shown.

The depletion region DR may include a first region R1 and the second region R2. The first region R1 may be configured to transport charge carriers (e.g., holes or electrons) generated within the single photon avalanche diode 1000 by light incident on the single photon avalanche diode 1000 to the second region R2. When operating the single photon avalanche diode 1000, an electric field of less than 3×10⁵ V/cm may be applied to the first region R1. For example, the charge carriers may be transferred to the second region R2 due to the electric field applied to the first region R1. The charge carriers may be generated across all regions of the single photon avalanche diode 1000. The charge carriers generated in regions other than the depletion region DR (hereinafter, referred to as a non-depletion region) can be transferred in random directions. Among the charge carriers generated in the non-depletion region, the charge carriers that reach the first region R1 may be transferred to the second region R2 by the electric field applied to the first region R1. The first region R1, the second region R2, and the non-depletion region (i.e., the depletion region DR and the non-depletion region) may all be referred to as carrier collection regions. The first region R1 may be formed in a region that overlaps the heavily doped region 106 and the guard ring 108 along the third direction D3. For example, the first region R1 may be provided between the second region R2 and the first well 104. The first region R1 may extend to a region between the guard ring 108 and a relief region 112.

The second region R2 may be configured to multiply the charge carriers transferred from the first region R1. For example, when operating the single photon avalanche diode 1000, an electric field having a magnitude of 3×10⁵ V/cm or more may be applied to the second region R2. The second region R2 may be formed between the heavily doped region 106 and the first region R1. For example, the second region R2 may be provided at and around the boundary between the first well 104 and the heavily doped region 106. The second region R2 may overlap the heavily doped region 106 along the third direction D3. The second region R2 may be provided between the guard ring 108 and the first well 104. The second region R2 may extend onto the boundary between the lower region of the guard ring 108 and the first well 104. For example, the second region R2 may be formed on a bottom surface of the guard ring 108. The second region R2 may overlap the guard ring 108 along the third direction D3. In example embodiments, the second region R2 may overlap a portion of the guard ring 108 along the third direction D3. In example embodiments, the second region R2 may overlap an entire guard ring 108 along the third direction D3. The second region R2 may be provided between the heavily doped region 106 and the first region R1 and between the guard ring 108 and the first region R1. The second region R2 may overlap the first region R1 along the third direction D3.

The contact region 110 may be provided on a side surface of the guard ring 108. The contact region 110 may be provided on the opposite side of the heavily doped region 106 with the guard ring 108 interposed therebetween. The contact region 110 may be exposed on the front side 100a. On the front side 100a, the contact region 110 may surround the guard ring 108. In another example embodiments, a plurality of the contact regions 110 may be provided. In this case, a plurality of the contact regions 110 each may be electrically connected to a circuit outside the single photon avalanche diode 1000. The contact region 110 may have the first conductivity type. A doping concentration of the contact region 110 may be higher than that of the first well 104. For example, the doping concentration of the contact region 110 may be 1×10¹⁵ to 2×10²¹ cm⁻³. In example embodiments, the contact region 110 may be electrically connected to at least one of the external power source, the DC-to-DC converter, and another power management integrated circuit. In example embodiments, the contact region 110 may be electrically connected to at least one of the quenching resistor (or the quenching circuit) and another pixel circuit.

The relief region 112 may be provided between the contact region 110 and the first well 104. The relief region 112 may be electrically connected to the contact region 110 and the first well 104. The relief region 112 may alleviate the difference between the contact region 110 and the first well 104. The relief region 112 may improve the electrically connecting characteristics of the contact region 110 and the first well 104. For example, the relief region 112 is configured to reduce or prevent a voltage drop when the voltage is applied to the first well 104 through the contact region 110. The relief region 112 is configured to ensure that the voltage is applied uniformly to the first well 104. The relief region 112 may extend along the contact region 110. The relief region 112 may be provided on side and bottom surfaces of the contact region 110. For example, the relief region 112 may directly contact the side and bottom surfaces of the contact region 110. In another embodiments, the relief region 112 may be configured to be provided only on the bottom surface of the contact region 110. For example, both side surfaces of the relief region 112 may be aligned with both side surfaces of the contact region 110. A bottom surface and the one side surface of the relief region 112 may contact the first well 104. The other side surface of the relief region 112 may contact the substrate region 102. In example embodiments, the other side surface of the relief region 112 may be aligned with a side surface of the first well 104 adjacent thereto. In example embodiments, the relief region 112 may protrude from the side surface of the first well 104. The relief region 112 may be exposed on the front side 100a. On the front side 100a, the relief region 112 may surround the guard ring 108. The relief region 112 may be spaced apart from the guard ring 108. The first well 104 may extend between the guard ring 108 and the relief region 112. For example, the region between the guard ring 108 and the relief region 112 may be filled with the first well 104. The first well 104 may be exposed on the front side 100a between the guard ring 108 and the relief region 112. The relief region 112 may have the first conductivity type. A doping concentration of the relief region 112 may be lower than that of the contact region 110 and may be similar to or higher than the doping concentration of the first well 104. For example, the doping concentration of the relief region 112 may be 1×10¹⁵ to 5×10¹⁷ cm⁻³.

The device isolation pattern 114 may be provided on the other side surface of the relief region 112. The device isolation pattern 114 may be exposed on the front side 100a. On the front side 100a, the device isolation pattern 114 may surround the relief region 112. The device isolation pattern 114 may include an electrically insulating material. For example, the device isolation pattern 114 may include silicon oxide (e.g., SiO₂), silicon nitride (e.g., SiN), silicon oxynitride (e.g., SiON), or a combination thereof. The device isolation pattern 114 may be formed, for example, by filling a recessed region formed by etching the semiconductor substrate 100 with an electrically insulating material (e.g., silicon oxide). For example, the device isolation pattern 114 may be shallow trench isolation (STI). The device isolation pattern 114 can electrically separate the single photon avalanche diode 1000 from other semiconductor devices (e.g., other single photon avalanche diodes 1000 or electronic devices constituting other circuits (e.g., transistor)). Although the device isolation pattern 114 is shown as being in contact with the contact region 110 and the relief region 112, this is exemplary. In another example embodiments, the device isolation pattern 114 may be spaced apart from the contact region 110 and the relief region 112.

When the second region R2 is formed only in an inner region of the guard ring 108, the amount of charge carriers that is not multiplied after being generated by light incident on the first well 104 and the substrate region 102 may be relatively large. The inner region of the guard ring 108 may refer to a region surrounded by the guard ring 108 from a plan view. In the present disclosure, the second region R2 is formed not only on the inner region of the guard ring 108 (i.e., the region overlapping with the heavily doped region 106 along the third direction D3) as well as the bottom surface of the guard ring 108, so that a relatively large amount of charge carriers may be multiplied. Accordingly, the light absorption efficiency of the single photon avalanche diode 1000 can be improved.

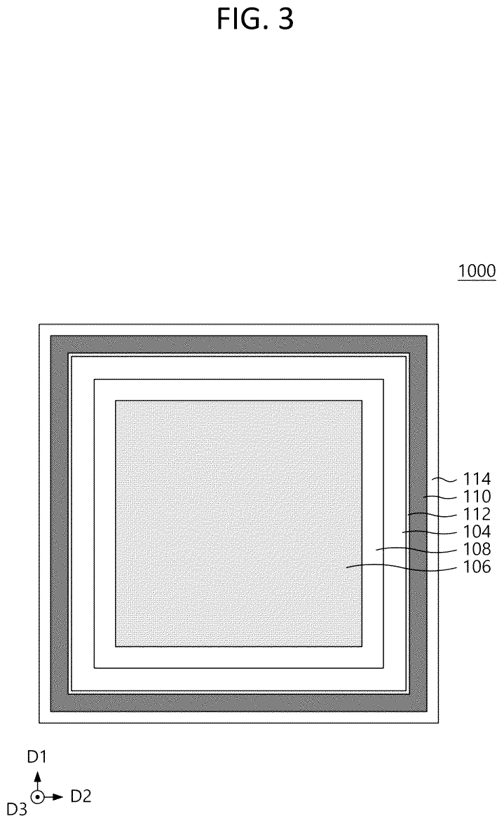

FIG. 3 is a plan view of the single photon avalanche diode of FIG. 2 according to example embodiments. Differences from those shown in FIG. 1 are described for brevity of explanation.

Referring to FIG. 3, a single photon avalanche diode 1000 may be provided. Unlike that shown in FIG. 1, the single photon avalanche diode 1000 may have a square shape. Specifically, the heavily doped region 106 may have a square shape, and the guard ring 108, the first well 104, the relief region 112, the contact region 110, and the device isolation pattern 114 may have a square ring shape surrounding the heavily doped region 106. The guard ring 108, the first well 104, the relief region 112, the contact region 110, and the device isolation pattern 114 may be sequentially arranged in a direction away from the heavily doped region 106. For example, the guard ring 108, the first well 104, the relief region 112, the contact region 110, and the device isolation pattern 114 may have the same center.

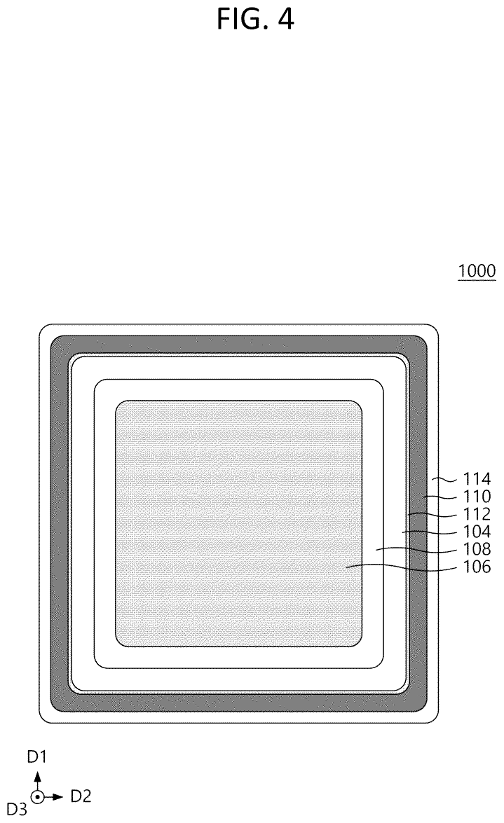

FIG. 4 is a plan view of the single photon avalanche diode of FIG. 2 according to example embodiments. Differences from those shown in FIG. 1 are described for brevity of explanation.

Referring to FIG. 4, a single photon avalanche diode 1000 may be provided. Unlike that shown in FIG. 1, the single photon avalanche diode 1000 may have a square shape with rounded corners. Specifically, the heavily doped region 106 may have a square shape with rounded corners. The guard ring 108, the first well 104, the relief region 112, the contact region 110, and the device isolation pattern 114 may have a square ring shape with rounded corners surrounding the heavily doped region 106. The guard ring 108, the first well 104, the relief region 112, the contact region 110, and the device isolation pattern 114 may be sequentially arranged in a direction away from the heavily doped region 106. For example, the heavily doped region 106, the guard ring 108, the first well 104, the relief region 112, the contact region 110, and the device isolation pattern 114 may have the same center.

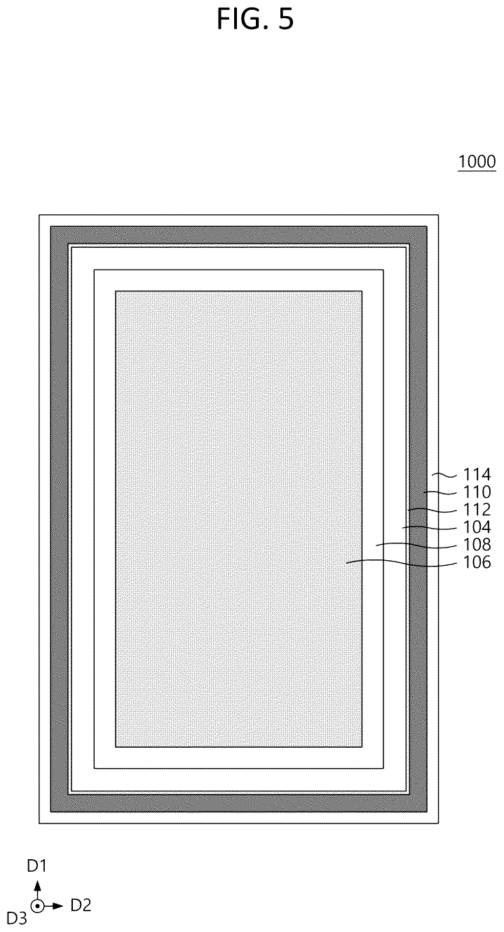

FIG. 5 is a plan view of the single photon avalanche diode of FIG. 2 according to example embodiments. Differences from those shown in FIG. 1 are described for brevity of explanation.

Referring to FIG. 5, a single photon avalanche diode 1000 may be provided. Unlike that shown in FIG. 1, the single photon avalanche diode 1000 may have a rectangular shape. Specifically, the heavily doped region 106 may have a rectangular shape rather than a square. The guard ring 108, the first well 104, the relief region 112, the contact region 110, and the device isolation pattern 114 may have a rectangular ring shape surrounding the heavily doped region 106. The guard ring 108, the first well 104, the relief region 112, the contact region 110, and the device isolation pattern 114 may be sequentially arranged in a direction away from the heavily doped region 106. For example, the heavily doped region 106, the guard ring 108, the first well 104, the relief region 112, the contact region 110, and the device isolation pattern 114 may have the same center.

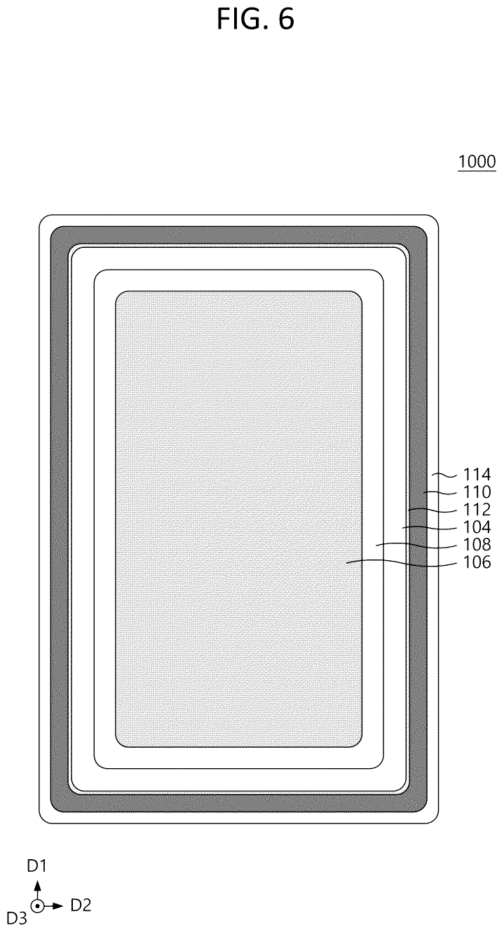

FIG. 6 is a plan view of the single photon avalanche diode of FIG. 2 according to example embodiments. Differences from those shown in FIG. 1 are described for brevity of explanation.

Referring to FIG. 6, a single photon avalanche diode 1000 may be provided. Unlike that shown in FIG. 1, the single photon avalanche diode 1000 may have a rectangular shape with rounded corners. Specifically, the heavily doped region 106 may have a rectangular shape with rounded corners. The guard ring 108, the first well 104, the relief region 112, the contact region 110, and the device isolation pattern 114 may have a rectangular ring shape with rounded corners surrounding the heavily doped region 106. The guard ring 108, the first well 104, the relief region 112, the contact region 110, and the device isolation pattern 114 may be sequentially arranged in the direction away from the heavily doped region 106. For example, the heavily doped region 106, the guard ring 108, the first well 104, the relief region 112, the contact region 110, and the device isolation pattern 114 may have the same center.

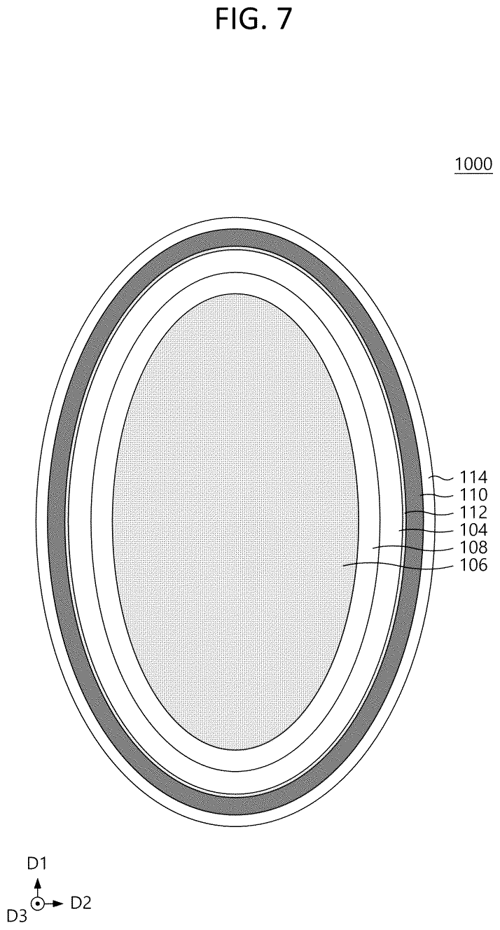

FIG. 7 is a plan view of the single photon avalanche diode of FIG. 2 according to example embodiments. Differences from those shown in FIG. 1 are described for brevity of explanation.

Referring to FIG. 7, a single photon avalanche diode 1000 may be provided. Unlike that shown in FIG. 1, the single photon avalanche diode 1000 may have an elliptical shape. Specifically, the heavily doped region 106 may have an oval shape. The guard ring 142, the relief region 112, the first well 104, the contact region 110, and the device isolation pattern 114 may have an elliptical ring shape surrounding the heavily doped region 106. The guard ring 142, the relief region 112, the first well 104, the contact region 110, and the device isolation pattern 114 may be sequentially arranged in a direction away from the heavily doped region 106. For example, the heavily doped region 106, the guard ring 108, the first well 104, the relief region 112, the contact region 110, and the device isolation pattern 114 may have the same center.

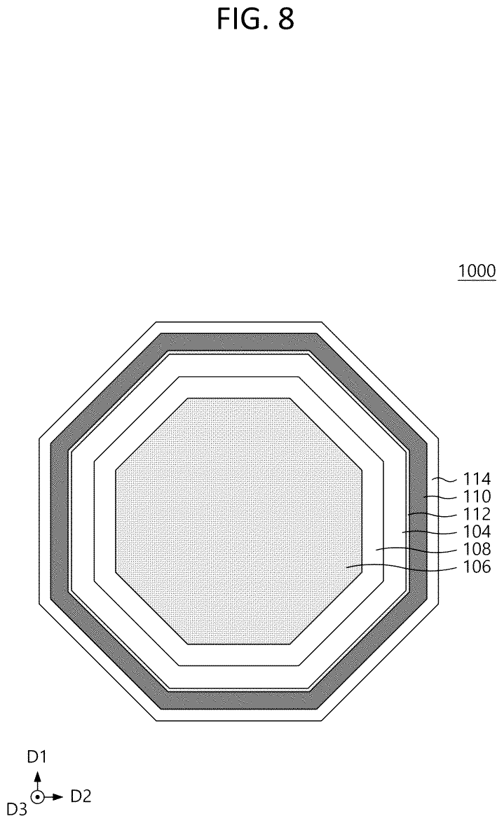

FIG. 8 is a plan view of the single photon avalanche diode of FIG. 2 according to example embodiments. Differences from those shown in FIG. 1 are described for brevity of explanation.

Referring to FIG. 8, a single photon avalanche diode 1000 may be provided. Unlike that shown in FIG. 1, the single photon avalanche diode 1000 may have an octagonal shape. Specifically, the heavily doped region 106 may have an octagonal shape. The guard ring 142, the relief region 112, the first well 104, the contact region 110, and the device isolation pattern 114 may have an octagonal ring shape surrounding the heavily doped region 106. The guard ring 142, the relief region 112, the first well 104, the contact region 110, and the device isolation pattern 114 may be sequentially arranged in a direction away from the heavily doped region 106. For example, the heavily doped region 106, the guard ring 108, the first well 104, the relief region 112, the contact region 110, and the device isolation pattern 114 may have the same center.

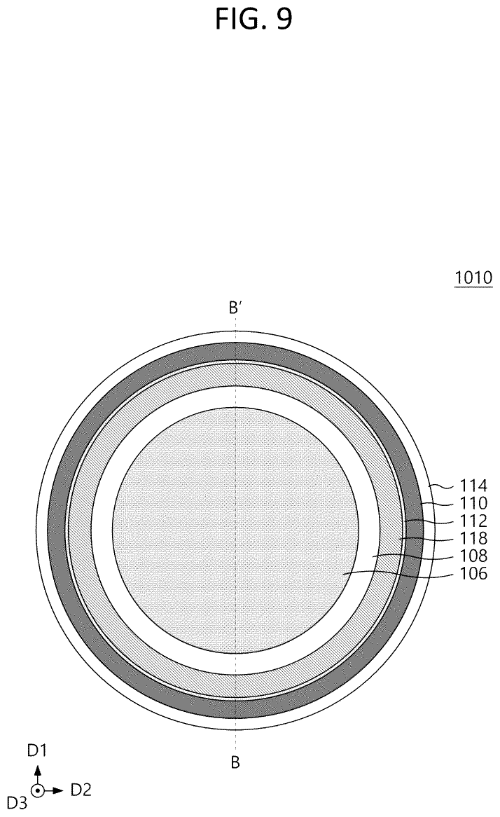

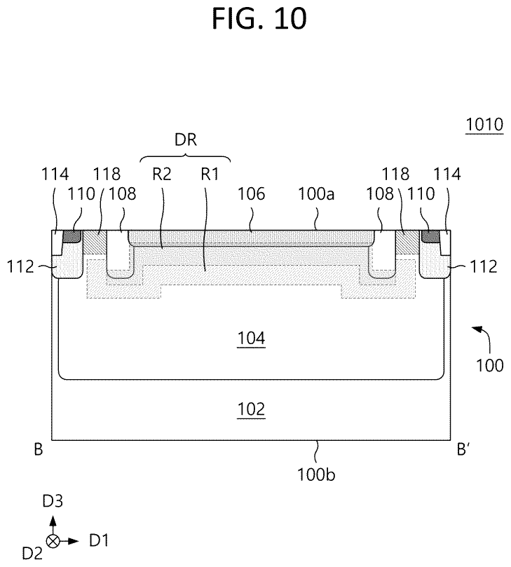

FIG. 9 is a plan view of a single photon avalanche diode according to example embodiments. FIG. 10 is a cross-sectional view corresponding to line B-B′ of the single photon avalanche diode of FIG. 9. For brevity of explanation, differences from those described with reference to FIGS. 1 and 2 are mainly described.

Referring to FIGS. 9 and 10, a single photon avalanche diode 1010 may be provided. Unlike the description with reference to FIGS. 1 and 2, the single photon avalanche diode 1010 may further include a virtual guard ring 118. The virtual guard ring 118 may be formed between the guard ring 108 and the relief region 112. The virtual guard ring 118 may be a portion of the first well 104 or the substrate region 102. For example, the virtual guard ring 118 may be formed as the doping concentration of the first well 104 decreases as it approaches the front side 100a. The virtual guard ring 118 may be configured to serve as an additional guard ring. Specifically, the virtual guard ring 118 can prevent the premature breakdown phenomenon by alleviating the concentration of the electric field in the portion of the depletion region DR. For example, the virtual guard ring 118 may be configured to alleviate a concentration of the electric field in the second region R2 formed on the bottom surface of the guard ring 108. The breakdown characteristics of the single photon avalanche diode 1010 can be improved by the virtual guard ring 118. The virtual guard ring 118 may surround the guard ring 108. For example, the virtual guard ring 118 may have a ring shape extending along the region between the guard ring 108 and the relief region 112.

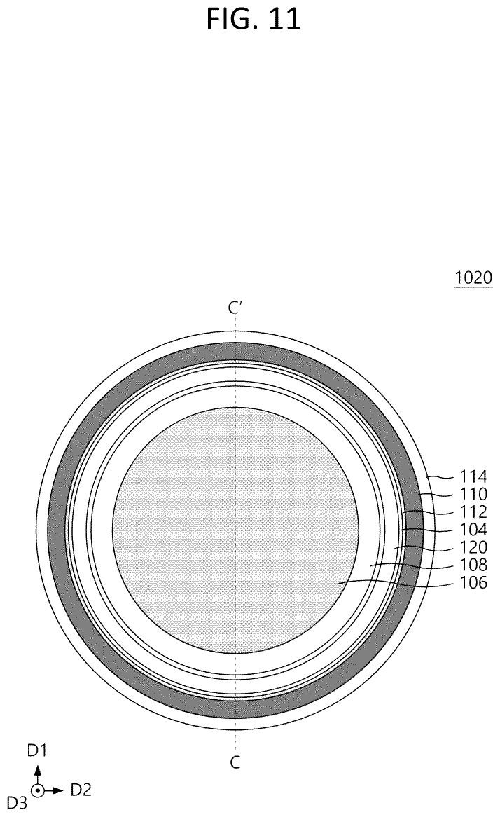

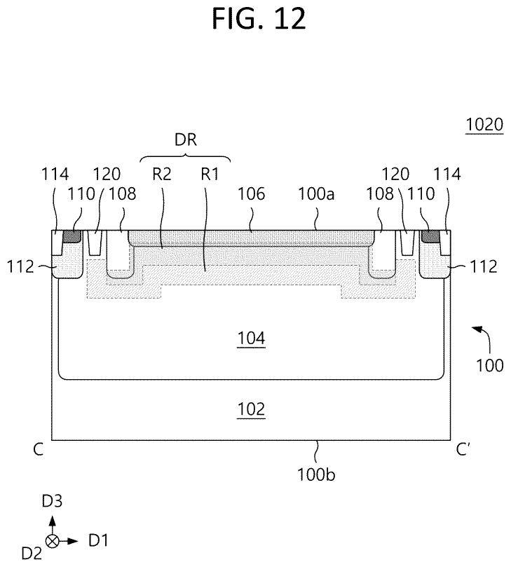

FIG. 11 is a plan view of a single photon avalanche diode according to example embodiments. FIG. 12 is a cross-sectional view corresponding to line C-C′ of the single photon avalanche diode of FIG. 11. For brevity of explanation, differences from those described with reference to FIGS. 1 and 2 are mainly described.

Referring to FIGS. 11 and 12, a single photon avalanche diode 1020 may be provided. Unlike the description with reference to FIGS. 1 and 2, the single photon avalanche diode 1020 may further include a first insulating pattern 120. The first insulating pattern 120 may be provided between the relief region 112 and the guard ring 108. The first insulating pattern 120 may be exposed on the front side 100a. The first insulating pattern 120 may surround the guard ring 108 on the front side 100a. The first insulating pattern 120 may include an electrically insulating material. For example, the first insulating pattern 120 may include silicon oxide (e.g., SiO₂), silicon nitride (e.g., SiN), silicon oxynitride (e.g., SiON), or a combination thereof. The first insulating pattern 120 may be formed, for example, by filling a recessed region formed by etching the semiconductor substrate 100 with an electrically insulating material. For example, the first insulating pattern 120 may be shallow trench isolation (STI). The first insulating pattern 120 may be formed on the semiconductor substrate 100 before the first well 104 is formed. For example, during an ion implantation process of implanting impurities into the semiconductor substrate 100 to form the first well 104, the first insulating pattern 120 may be configured to reduce an ion implantation effect on the region (i.e., the first well 104) located below the first insulating pattern 120. Compared to the case without the first insulating pattern 120, a doping concentration in one region of the first well 104 located below the first insulating pattern 120 may be lowered when the first insulating pattern 120 is present. Accordingly, the depletion region DR (i.e., the first region R1 and the second region R2) may be formed widely, and thus the fill factor and light absorption efficiency can be improved. The present disclosure can provide the single photon avalanche diode 1020 with improved fill factor and light absorption efficiency.

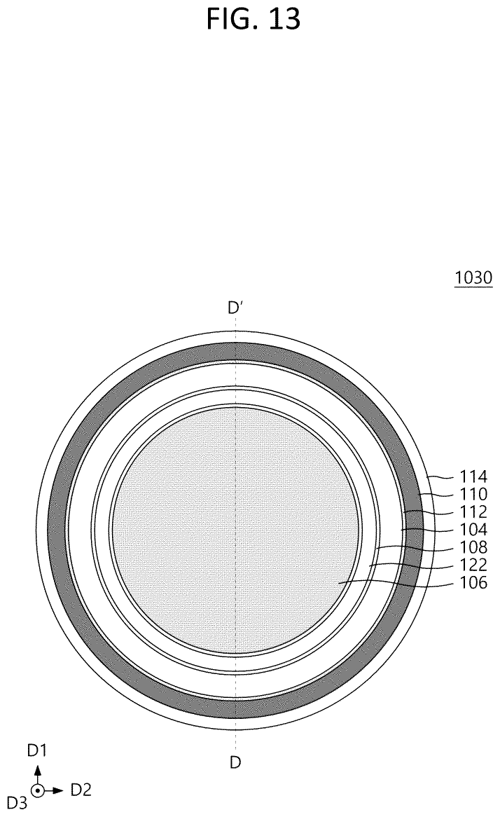

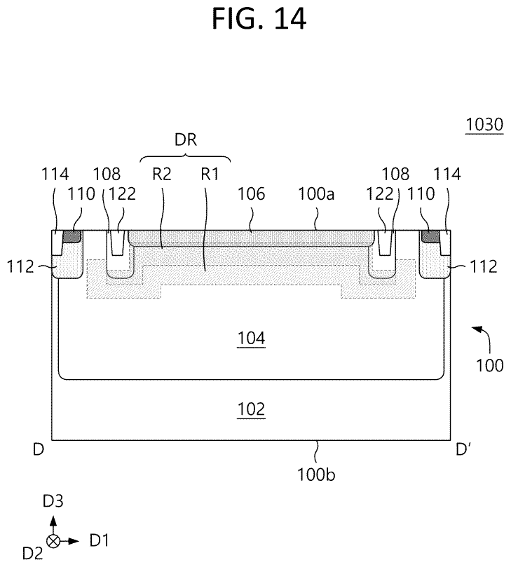

FIG. 13 is a plan view of a single photon avalanche diode according to example embodiments. FIG. 14 is a cross-sectional view corresponding to line D-D′ of the single photon avalanche diode of FIG. 13. For brevity of explanation, differences from those described with reference to FIGS. 1 and 2 are mainly described.

Referring to FIGS. 13 and 14, a single photon avalanche diode 1030 may be provided. Unlike the description with reference to FIGS. 1 and 2, the single photon avalanche diode 1030 may further include a second insulating pattern 122. The second insulating pattern 122 may be provided on the guard ring 108. The second insulating pattern 122 may overlap the guard ring 108 along the third direction D3. The second insulating pattern 122 may surround the heavily doped region 106. For example, the second insulating pattern 122 may have a ring shape extending along the side surface of the heavily doped region 106. Although the second insulating pattern 122 is shown to be spaced apart from the heavily doped region 106, this is exemplary. In another example embodiments, the second insulating pattern 122 may directly contact the heavily doped region 106. The second insulating pattern 122 may be formed from the same height as the top surface of the heavily doped region 106 to a certain depth. A depth of the second insulating pattern 122 may be determined as needed. The second insulating pattern 122 may be inserted into the guard ring 108. For example, side and bottom surfaces of the second insulating pattern 122 may directly contact the guard ring 108. A top surface of the second insulating pattern 122 may be exposed to a top surface of the semiconductor substrate 100. The second insulating pattern 122 may include an electrically insulating material. For example, the second insulating pattern 122 may include silicon oxide (e.g., SiO₂), silicon nitride (e.g., SiN), silicon oxynitride (e.g., SiON), or a combination thereof. In example embodiments, the second insulating pattern 122 may be shallow trench isolation (STI) formed by etching a portion of the semiconductor substrate 100 and then filling the etched region with an electrically insulating material. The second insulating pattern 122 can reduce or prevent the premature breakdown phenomenon by alleviating the concentration of the electric field in the portion of the doped region DR. The second insulating pattern 122 can reduce or prevent the influence of surface noise components. The second insulating pattern 122 may be formed on the semiconductor substrate 100 before the first well 104 and the guard ring 108 are formed. The second insulating pattern 122 may reduce a doping concentration of the region located below it. For example, during an ion implantation process of implanting impurities into the semiconductor substrate 100 to form the first well 104 and the guard ring 108, the second insulating pattern 122 may be configured to reduce an ion implantation effect on region (i.e., the first well 104 and the guard ring 108) located below the second insulating pattern 122. Compared to the case without the second insulating pattern 122, a doping concentration of the first well 104 and the guard ring 108 located below the second insulating pattern 122 may be lowered when the second insulating pattern 122 is present. Accordingly, the depletion region DR (i.e., the first region R1 and the second region R2) may be formed widely, and thus the fill factor and light absorption efficiency can be improved. The present disclosure can provide the single photon avalanche diode 1030 with improved fill factor and light absorption efficiency.

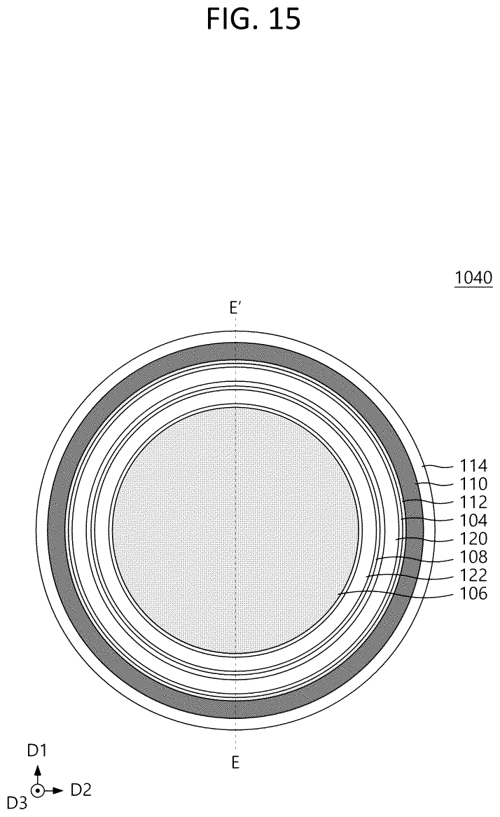

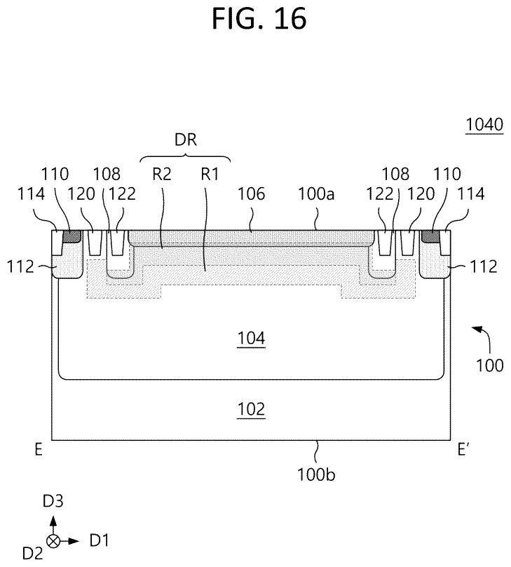

FIG. 15 is a plan view of a single photon avalanche diode according to example embodiments. FIG. 16 is a cross-sectional view corresponding to line E-E′ of the single photon avalanche diode of FIG. 15. For brevity of explanation, content substantially the same as that described with reference to FIGS. 1 and 2, that described with reference to FIGS. 11 and 12, and that described with reference to FIGS. 13 and 14 will not be described.

Referring to FIGS. 15 and 16, a single photon avalanche diode 1040 may be provided. The single photon avalanche diode 1040, unlike the single photon avalanche diode 1000 described with reference to FIGS. 1 and 2, may further include a first insulating pattern 120 and a second insulating pattern 122. The first insulating pattern 120 may be substantially the same as the first insulating pattern 120 described with reference to FIGS. 11 and 12. The second insulating pattern 122 may be substantially the same as the second insulating pattern 122 described with reference to FIGS. 13 and 14. Accordingly, the depletion region DR (i.e., the first region R1 and the second region R2) may be formed widely, and thus the fill factor and light absorption efficiency can be improved. The present disclosure can provide the single photon avalanche diode 1040 with improved fill factor and light absorption efficiency.

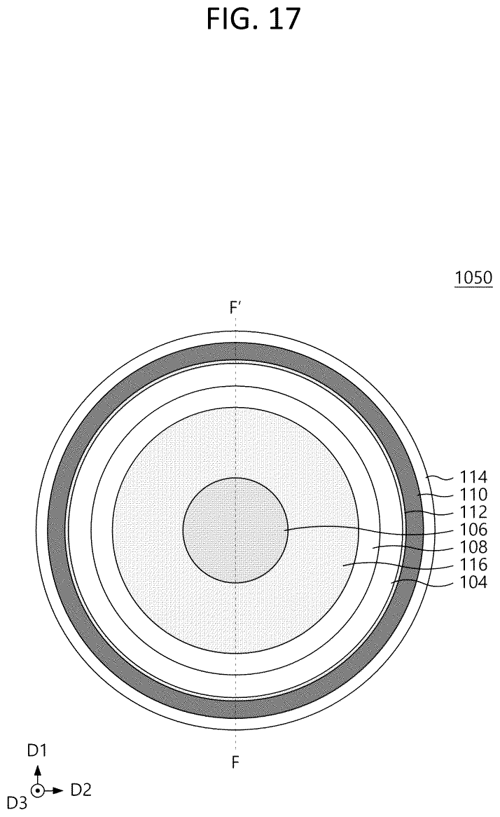

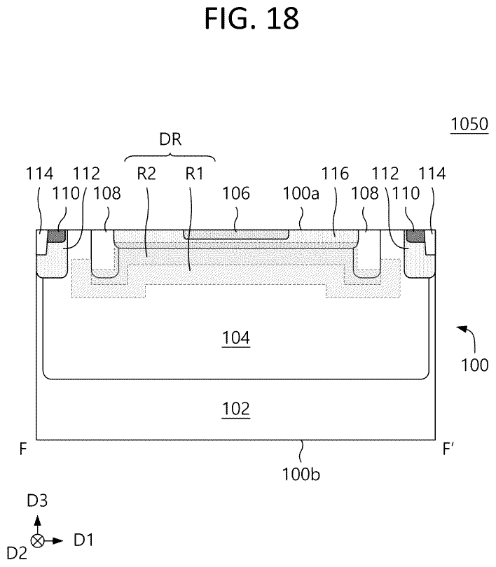

FIG. 17 is a plan view of a single photon avalanche diode according to example embodiments. FIG. 18 is a cross-sectional view corresponding to line F-F′ of the single photon avalanche diode of FIG. 17. For brevity of explanation, differences from those described with reference to FIGS. 1 and 2 are mainly described.

Referring to FIGS. 17 and 18, a single photon avalanche diode 1050 may be provided. Unlike the description with reference to FIGS. 1 and 2, the single photon avalanche diode 1050 may further include a lightly doped region 116. The lightly doped region 116 may be provided between the first well 104 and the heavily doped region 106. The lightly doped region 116 may contact the bottom and side surfaces of the heavily doped region 106. The lightly doped region 116 may be exposed on the front side 100a. On the front side 100a, the lightly doped region 116 may surround the heavily doped region 106. The lightly doped region 116 may have the second conductivity type. The lightly doped region 116 may have a lower doping concentration than the doping concentration of the heavily doped region 106. For example, the doping concentration of the lightly doped region 116 may be 1×10¹⁵ to 1×10¹⁹ cm⁻³. The lightly doped region 116 may be configured to form the depletion region DR in contact with the first well 104. The lightly doped region 116 may be configured to reduce or prevent the tunneling effect that occurs as the size of the semiconductor device is decreased. For example, the tunneling effect may result in current flows even though no photon is incident on the single photon avalanche diode 1050. By forming the depletion region DR using the lightly doped region 116, the tunneling noise and trap-assisted tunneling noise of the single photon avalanche diode 1050 can be reduced and the operating wavelength band of the single photon avalanche diode 1050 can be widened.

In example embodiments, as described with reference to FIGS. 11 and 12, a first insulating pattern 120 may be provided between the relief region 112 and the guard ring 108. In example embodiments, as described with reference to FIGS. 13 and 14, a second insulating pattern 122 may be provided on the guard ring 108. In example embodiments, as described with reference to FIGS. 15 and 16, a first insulating pattern 120 is provided between the relief region 112 and the guard ring 108, and a second insulating pattern 122 is provided on the guard ring 108.

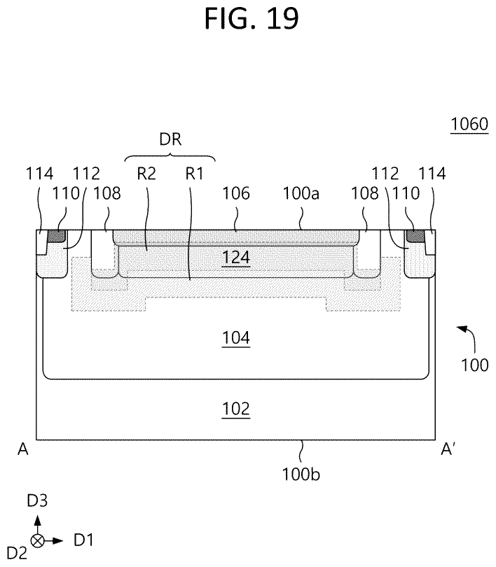

FIG. 19 is a cross-sectional view corresponding to line A-A′ of the single photon avalanche diode of FIG. 1. For brevity of explanation, differences from those described with reference to FIGS. 1 and 2 are mainly described.

Referring to FIG. 19, a single photon avalanche diode 1060 may be provided. Unlike the description with reference to FIGS. 1 and 2, the single photon avalanche diode 1060 may further include a second well 124. The second well 124 may be provided between the first well 104 and the heavily doped region 106. The second well 124 may separate the first well 104 and the heavily doped region 106 from each other. For example, the second well 124 may directly contact the first well 104 and the heavily doped region 106. The second well 124 may be provided in the inner region of the guard ring 108 having a ring shape. From a perspective facing at the front side 100a, the second well 124 may be surrounded by the guard ring 108. For example, the second well 124 may directly contact the guard ring 108. In example embodiments, the second well 124 and the guard ring 108 may be formed to substantially the same depth. The depth may refer to a distance from the front side 100a. For example, a bottom surface of the second well 124 and the bottom surface of the guard ring 108 may be located at substantially the same depth. However, the depth of the second well 124 may not be limited to the same as that of the guard ring 108. In example embodiments, the second well 124 may be formed to the depth that is deeper or shallower than that of the guard ring 108. The second well 124 may have the first conductivity type. For example, a doping concentration of the second well 124 may be 1×10¹⁵ to 5×10¹⁷ cm⁻³. In example embodiments, the second well 124 may have a uniform doping concentration. In example embodiments, the doping concentration of the second well 124 may be decreased as it approaches the heavily doped region 106. However, the distribution of the doping concentration of the second well 124 may be determined as needed. For example, the doping concentration of the second well 124 may be increased as it approaches the heavily doped region 106, or may be increased and then decreased as it approaches the heavily doped region 106. The second well 124 may enhance the avalanche effect by increasing the electric field in the depletion region DR. The second well 124 may be configured to improve the characteristics of charge carriers (i.e., electrons or holes) being transferred from the first well 104 to the heavily doped region 106.

In example embodiments, as described with reference to FIGS. 11 and 12, a first insulating pattern 120 may be provided between the relief region 112 and the guard ring 108. In example embodiments, as described with reference to FIGS. 13 and 14, a second insulating pattern 122 may be provided on the guard ring 108. In example embodiments, as described with reference to FIGS. 15 and 16, a first insulating pattern 120 is provided between the relief region 112 and the guard ring 108, and a second insulating pattern 122 is provided on the guard ring 108.

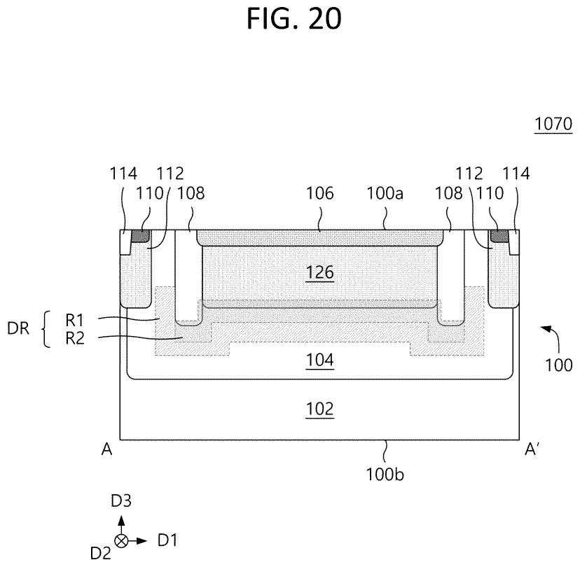

FIG. 20 is a cross-sectional view corresponding to line A-A′ of the single photon avalanche diode of FIG. 1. For brevity of explanation, differences from those described with reference to FIGS. 1 and 2 are mainly described.

Referring to FIG. 20, a single photon avalanche diode 1070 may be provided. Unlike the description with reference to FIGS. 1 and 2, the single photon avalanche diode 1070 may further include a third well 126. The third well 126 may be provided between the first well 104 and the heavily doped region 106. The third well 126 may separate the first well 104 and the heavily doped region 106 from each other. For example, the third well 126 may directly contact the first well 104 and the heavily doped region 106. The third well 126 may be provided in the inner region of the guard ring 108 having a ring shape. From a perspective facing at the front side 100a, the third well 126 may be surrounded by the guard ring 108. For example, the third well 126 may directly contact the guard ring 108. In example embodiments, the third well 126 may be formed to a shallower depth than that of the guard ring 108. The depth may refer to a distance from the front side 100a. For example, a bottom surface of the third well 126 may be located closer to the front side 100a than the bottom surface of the guard ring 108. The guard ring 108 may protrude from the bottom surface of the third well 126. The third well 126 may have the second conductivity type. A doping concentration of the third well 126 may be lower than that of the heavily doped region 106 and may be higher than that of the guard ring 108. For example, the doping concentration of the third well 126 may be 1×10¹⁵ to 5×10¹⁷ cm⁻³. The depletion region DR may be formed adjacent to a boundary between the third well 126 and the first well 104. The third well 126 may have a lower doping concentration than that of the heavily doped region 106. The depletion region DR may be formed widely by the third well 126.

In example embodiments, as described with reference to FIGS. 11 and 12, a first insulating pattern 120 may be provided between the relief region 112 and the guard ring 108. In example embodiments, as described with reference to FIGS. 13 and 14, a second insulating pattern 122 may be provided on the guard ring 108. In example embodiments, as described with reference to FIGS. 15 and 16, a first insulating pattern 120 is provided between the relief region 112 and the guard ring 108, and a second insulating pattern 122 is provided on the guard ring 108.

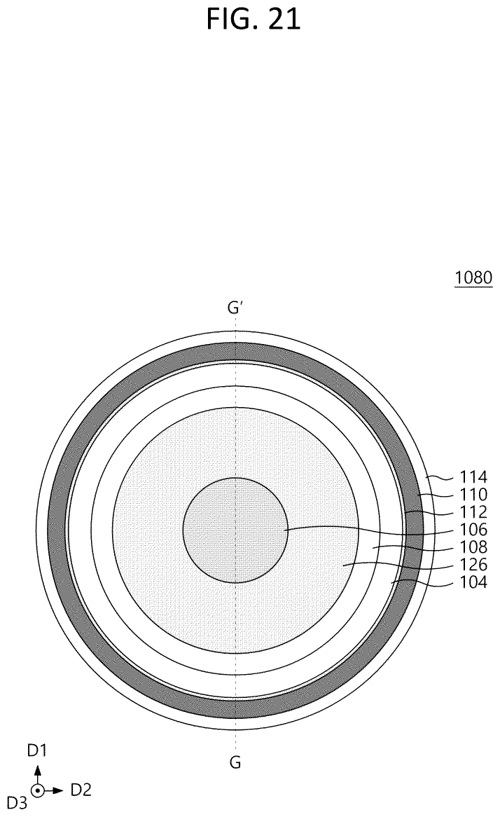

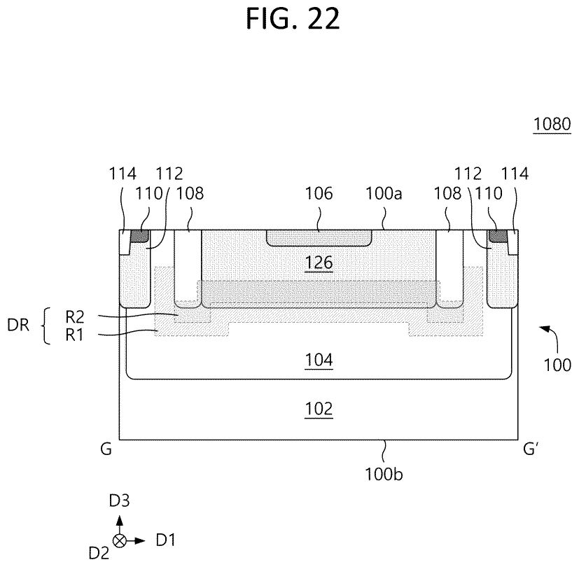

FIG. 21 is a plan view of a single photon avalanche diode according to example embodiments. FIG. 22 is a cross-sectional view corresponding to line G-G′ of the single photon avalanche diode of FIG. 21. For brevity of explanation, differences from the description with reference to FIGS. 1 and 2, the description with reference to FIGS. 11 and 12, the description with reference to FIGS. 13 and 14, and the description with reference to FIG. 20 are described in detail.

Referring to FIGS. 21 and 22, a single photon avalanche diode 1080 may be provided. Unlike the description with reference to FIGS. 1 and 2, the single photon avalanche diode 1080 may further include a third well 126. The third well 126 may be substantially the same as the third well 126 described with reference to FIG. 20.

Unlike the description with reference to FIG. 20, the third well 126 and the guard ring 108 may be formed to substantially the same depth. For example, a bottom surface of the third well 126 and the bottom surface of the guard ring 108 may be located at substantially the same depth. The heavily doped region 106 may be inserted into an upper portion of the third well 126. On the front side 100a, the heavily doped region 106 may be surrounded by the third well 126. The side and bottom surfaces of the heavily doped region 106 may contact the third well 126.

In example embodiments, unlike the description with reference to FIG. 20, the third well 126 and the guard ring 108 are formed to substantially the same depth. As described with reference to FIGS. 19 and 20, the heavily doped region 106 may have a larger width than that of the third well 126.

In example embodiments, unlike the description with reference to FIG. 20, the heavily doped region 106 may be inserted into the upper portion of the third well 126. As described with reference to FIG. 20, the third well 126 may be formed to a shallower depth than that of the guard ring 108.

In example embodiments, unlike the description with reference to FIG. 20, the heavily doped region 106 may be inserted into the upper portion of the third well 126, and the third well 126 may be formed to a greater depth than the guard ring 108.

In example embodiments, as described with reference to FIGS. 11 and 12, a first insulating pattern 120 may be provided between the relief region 112 and the guard ring 108. In example embodiments, as described with reference to FIGS. 13 and 14, a second insulating pattern 122 may be provided on the guard ring 108. In example embodiments, as described with reference to FIGS. 15 and 16, a first insulating pattern 120 is provided between the relief region 112 and the guard ring 108, and a second insulating pattern 122 is provided on the guard ring 108.

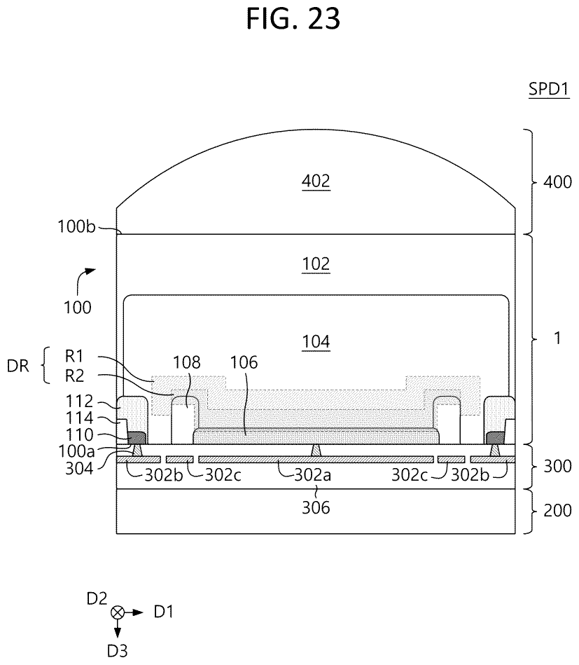

FIG. 23 is a cross-sectional view of a single photon detector according to example embodiments. For brevity of explanation, content substantially the same as that described with reference to FIGS. 1 and 2 may not be described.

Referring to FIG. 23, a single photon detector SPD1 may be provided. The single photon detector SPD1 may include a single photon avalanche diode layer 1, a control layer 200, a connection layer 300, and a lens unit 400. The single photon avalanche diode layer 1 may be substantially the same as the single photon avalanche diode 1000 described with reference to FIGS. 1 and 2. However, this is exemplary. In another example embodiments, the single photon avalanche diode layer 1 may be any one of the single photon avalanche diodes 1010 to 1080 described above. For convenience of explanation, the single photon avalanche diode layer 1 is shown as a reversed the top and bottom of the single photon avalanche diode 1000 shown in FIG. 2. The single photon detector SPD1 may be a backside illumination (BSI) type image sensor. The backside illumination type may refer to a type in which light is incident on the back side 100b of the semiconductor substrate 100. A frontside illumination (FSI) type may refer to a type in which light is incident on the front side 100a of the semiconductor substrate 100.

The control layer 200 may be provided on the front side 100a of the semiconductor substrate 100. The control layer 200 may include a circuit necessary for operating the single photon avalanche diode layer 1. For example, the control layer 200 may be a chip on which the circuit is formed. The circuit may be implemented by various electronic devices as needed. The circuit may include a quenching resistor (or a quenching circuit) and a pixel circuit. The quenching resistor (or the quenching circuit) may be configured to stop the avalanche effect and allow the single photon avalanche diode layer 1 to detect another photon. The pixel circuit may be composed of a reset or a recharge circuit, a memory, an amplifier circuit, a counter, a gate circuit, a time-to-digital converter, and the like. The circuit may also include a DC-to-DC converter and other power management integrated circuits. The circuit may transmit a signal to the single photon avalanche diode layer 1 or receive a signal from the single photon avalanche diode layer 1.

The connection layer 300 may be provided between the single photon avalanche diode layer 1 and the control layer 200. The connection layer 300 may include an insulating layer 306, an output pattern 302a, a bias pattern 302b, a shield pattern 302c, and a vertical connection 304. For example, the insulating layer 306 may include silicon oxide (e.g., SiO₂), silicon nitride (e.g., SiN), silicon oxynitride (e.g., SiON), or a combination thereof. For example, the vertical connection 304 may include a contact or a via.

The output pattern 302a may be electrically connected to the heavily doped region 106. The output pattern 302a may include an electrically conductive material. For example, the output pattern 302a may include copper (Cu), aluminum (Al), tungsten (W), titanium (Ti), titanium nitride (TiN), or a combination thereof. The output pattern 302a may electrically connect the heavily doped region 106 and the circuit of the control layer 200. For example, the vertical connection 304 may be provided between the heavily doped region 106 and the output pattern 302a. A Cu-Cu bond may be provided between the output pattern 302a and the control layer 200. The output pattern 302a may be configured to extract a detection signal from the single photon avalanche diode layer 1.

The bias pattern 302b may be electrically connected to the contact region 110. The bias pattern 302b may include an electrically conductive material. For example, the bias pattern 302b may include copper (Cu), aluminum (Al), tungsten (W), titanium (Ti), titanium nitride (TiN), or a combination thereof. The bias pattern 302b may electrically connect the contact region 110 and the circuit of the control layer 200. For example, the vertical connection 304 may be provided between the contact region 110 and the bias pattern 302b. The Cu-Cu bond may be provided between the bias pattern 302b and the control layer 200. The bias pattern 302b may be configured to apply a bias to the single photon avalanche diode layer 1.

The shield pattern 302c may electrically shield between the output pattern 302a and the bias pattern 302b. For example, the shield pattern 302c may be configured so that the detection signal extracted by the output pattern 302a is not affected by the bias signal applied to the bias pattern 302b. The shield pattern 302c may be electrically separated from the output pattern 302a and the bias pattern 302b. For example, the shield pattern 302c may be spaced apart from the output pattern 302a and the bias pattern 302b.

The output pattern 302a, the bias pattern 302b, and shield pattern 302c may serve as a reflective layer. Light that is not absorbed in the single photon avalanche diode layer 1 may be reflected by the output pattern 302a, the bias pattern 302b, and shield pattern 302c, and light is returned to the single photon avalanche diode layer 1. Accordingly, the light absorption efficiency of the single photon avalanche diode layer 1 can be improved.

The lens unit 400 may be provided on the back side 100b of the semiconductor substrate 100. The lens unit 400 may include a lens 402. The lens 402 may focus incident light and transmit it to the single photon avalanche diode layer 1. For example, the lens 402 may include a microlens, a Fresnel lens, or a metalens. However, a type of the lens 402 is not limited and may be determined as needed. In example embodiments, a central axis of the lens 402 may be aligned with a central axis of the single photon avalanche diode layer 1. The central axis of the lens 402 and the central axis of the single photon avalanche diode layer 1 may pass through the center of the lens 402 and the center of the single photon avalanche diode layer 1, respectively. The central axis of the lens 402 and the central axis of the single photon avalanche diode layer 1 may be a virtual axis parallel to a stacking direction (i.e., the third direction D3) of the lens 402 and the single photon avalanche diode layer 1. In example embodiments, the central axis of the lens 402 may be misaligned with the central axis of the single photon avalanche diode layer 1. In example embodiments, a width of the lens 402 may be approximately half a width of the single photon avalanche diode layer 1. In example embodiments, the lens 402 may be arranged in a 2×2 array. In example embodiments, at least one optical element may be inserted between the lens 402 and the single photon avalanche diode layer 1. For example, the optical elements include a color filter, a bandpass filter, a metal grid, an air grid, a grid based on a low refractive index material, an anti-reflective coating, a 2D nanomaterial layer, or an organic material layer. In example embodiments, the anti-reflective coating may be formed on a top of the lens 402.

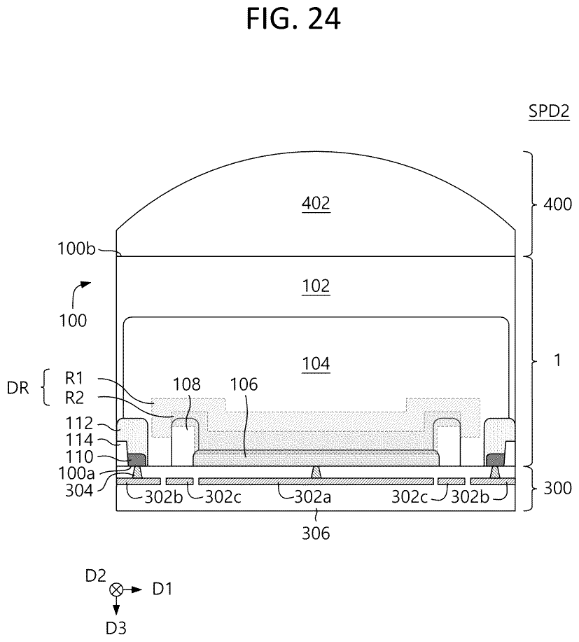

FIG. 24 is a cross-sectional view of a single photon detector according to example embodiments. For brevity of explanation, differences from those described with reference to FIG. 23 are described.

Referring to FIG. 24, a single photon detector SPD2 may be provided. The single photon detector SPD2 may include a single photon avalanche diode layer 1, a connection layer 300, and a lens unit 400. Unlike the description with reference to FIG. 23, a circuit necessary for operating the single photon avalanche diode layer 1 may be formed in the single photon avalanche diode layer 1. For example, the circuit may be provided in a region adjacent to the front side 100a of the semiconductor substrate 100. The circuit may be implemented by various electronic devices as needed. The circuit may include a quenching resistor (or a quenching circuit) and a pixel circuit. The quenching resistor (or the quenching circuit) may be configured to stop the avalanche effect and allow the single photon avalanche diode layer 1 to detect another photon. The pixel circuit may be composed of a reset or a recharge circuit, a memory, an amplifier circuit, a counter, a gate circuit, a time-to-digital converter, and the like. The circuit may also include a DC-to-DC converter and other power management integrated circuits. The circuit may transmit a signal to the single photon avalanche diode layer 1 or receive a signal from the single photon avalanche diode layer 1.

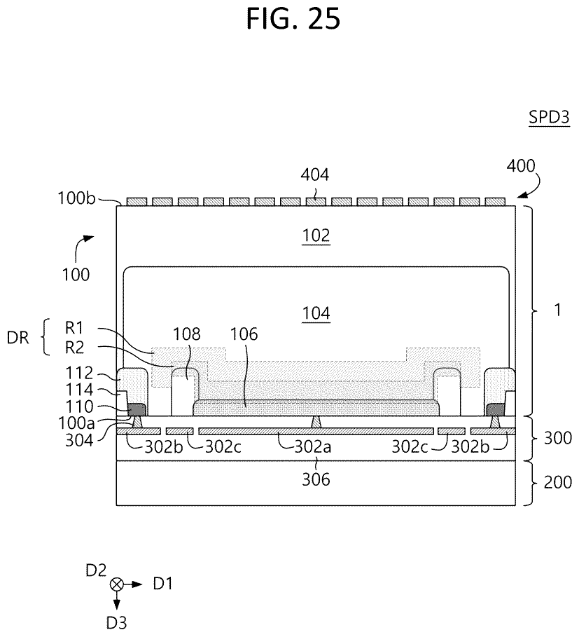

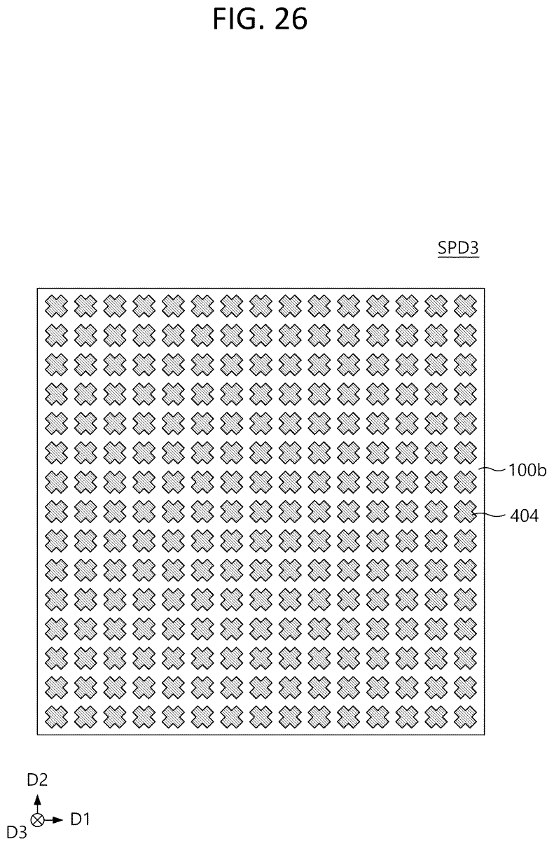

FIG. 25 is a cross-sectional view of a single photon detector according to example embodiments. FIG. 26 is a plan view of first diffraction patterns of FIG. 25. For brevity of explanation, content substantially the same as that described with reference to FIG. 23 may not be described.

Referring to FIG. 25, a single photon detector SPD3 may be provided. The single photon detector SPD3 may include a single photon avalanche diode layer 1, a control layer 200, a connection layer 300, and a lens unit 400. Unlike the description with reference to FIG. 23, the lens unit 400 may include first diffraction patterns 404 instead of the lens 402. The first diffraction patterns 404 may diffract incident light and increase the absorption length of light within the single photon avalanche diode layer 1. In another example embodiments, scattering patterns may be provided on the back side 100b of the single photon avalanche diode layer 1 instead of the first diffraction patterns 404. The scattering patterns may be, for example, cross or X-shaped patterns. In another example embodiments, the scattering patterns may be a combination of the cross and X-shaped patterns, or a connection of the cross and X-shaped patterns each other. The light absorption efficiency of the single photon avalanche diode layer 1 can be improved by the lens unit 400. In example embodiments, at least one optical element may be inserted between the first diffraction patterns 404 and the single photon avalanche diode layer 1. For example, the optical elements include a color filter, a bandpass filter, a metal grid, an air grid, a grid based on a low refractive index material, an anti-reflective coating, a 2D nanomaterial layer, or an organic material layer.

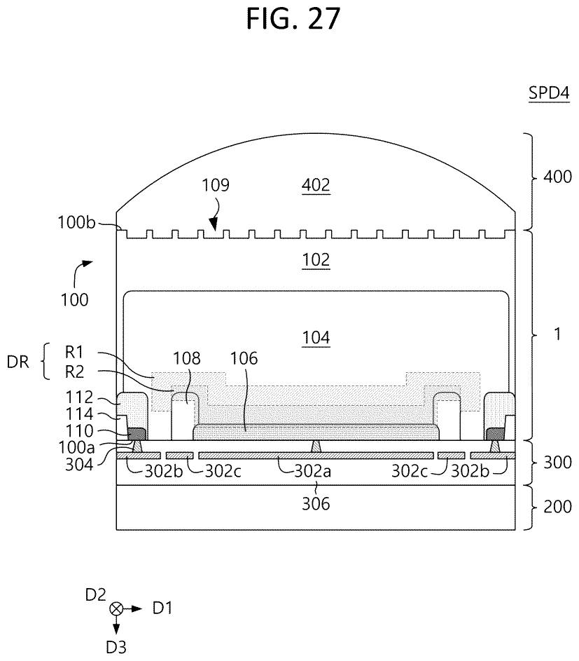

FIG. 27 is a cross-sectional view of a single photon detector according to example embodiments. For brevity of explanation, content substantially the same as that described with reference to FIG. 23 may not be described.

Referring to FIG. 27, a single photon detector SPD4 may be provided. The single photon detector SPD4 may include a single photon avalanche diode layer 1, a control layer 200, a connection layer 300, and a lens unit 400. Unlike the description with reference to FIG. 23, second diffraction patterns 109 may be provided on the back side 100b of the semiconductor substrate 100. For example, the second diffraction patterns 109 may be formed by etching the back side 100b of the semiconductor substrate 100. The second diffraction patterns 109 may diffract incident light and increase the absorption length of light within the single photon avalanche diode layer 1. In another example embodiments, scattering patterns may be formed on the back side 100b of the semiconductor substrate 100 instead of the second diffraction patterns 109. The scattering patterns may be formed by etching the back side 100b of the single photon avalanche diode layer 1. The scattering patterns may be, for example, cross or X-shaped patterns. In another example embodiments, the scattering patterns may be a combination of the cross and X-shaped patterns, or a connection of the cross and X-shaped patterns each other.

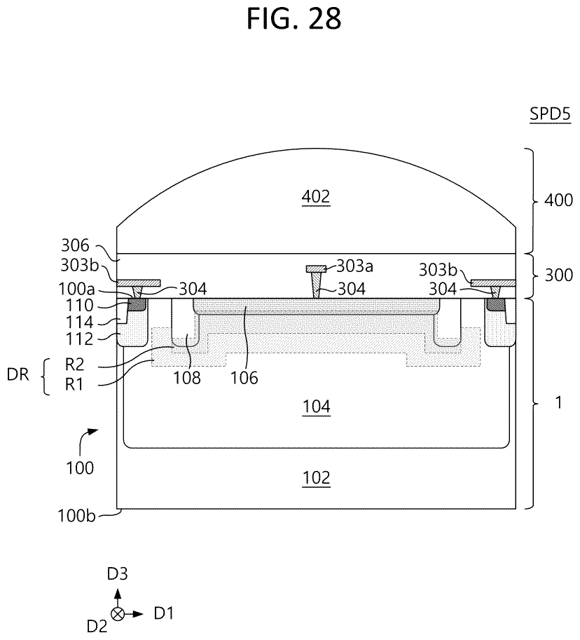

FIG. 28 is a cross-sectional view of a single photon detector according to example embodiments. For brevity of explanation, content substantially the same as that described with reference to FIGS. 1 and 2 may not be described.

Referring to FIG. 28, a single photon detector SPD5 may be provided. The single photon detector SPD5 may include a single photon avalanche diode layer 1, a connection layer 300, and a lens unit 400. The single photon detector SPD5 may be the frontside illumination (FSI) type image sensor. The single photon avalanche diode layer 1 may be substantially the same as the single photon avalanche diode 1000 described with reference to FIGS. 1 and 2. However, this is exemplary. In another example embodiments, the single photon avalanche diode layer 1 may be any one of the single photon avalanche diodes 1010 to 1080 described above.

The single photon avalanche diode layer 1 may include a circuit necessary for operating the single photon avalanche diode layer 1 in a region adjacent to the front side 100a of the semiconductor substrate 100. The circuit may be implemented by various electronic devices as needed. The circuit may include a quenching resistor (or a quenching circuit) and a pixel circuit. The quenching resistor (or the quenching circuit) may be configured to stop the avalanche effect and allow the single photon avalanche diode layer 1 to detect another photon. The pixel circuit may be composed of a reset or recharge circuit, a memory, an amplifier circuit, a counter, a gate circuit, a time-to-digital converter, and the like. The circuit may also include a DC-to-DC converter and other power management integrated circuits. The circuit may transmit a signal to the single photon avalanche diode layer 1 or receive a signal from the single photon avalanche diode layer 1.

The connection layer 300 may be provided between the single photon avalanche diode layer 1 and the lens unit 400. The connection layer 300 may include an insulating layer 306, an output conductive line 303a, a bias conductive line 303b, and a vertical connection 304. For example, the insulating layer 306 may include silicon oxide (e.g., SiO₂), silicon nitride (e.g., SiN), silicon oxynitride (e.g., SiON), or a combination thereof. For example, the vertical connection 304 may include a contact or a via.

The output conductive line 303a may be electrically connected to the heavily doped region 106. The output conductive line 303a may include an electrically conductive material. For example, the output conductive line 303a may include copper (Cu), aluminum (Al), tungsten (W), titanium (Ti), titanium nitride (TiN), or a combination thereof. The output conductive line 303a may electrically connect the heavily doped region 106 and the circuit included in the single photon avalanche diode layer 1. For example, the vertical connection 304 may be provided between the heavily doped region 106 and the output conductive line 303a and between the output conductive line 303a and the circuit. The output conductive line 303a may be configured to extract a detection signal from the single photon avalanche diode layer 1.

The bias conductive line 303b may be electrically connected to the contact region 110. The bias conductive line 303b may include an electrically conductive material. For example, the bias conductive line 303b may include copper (Cu), aluminum (Al), tungsten (W), titanium (Ti), titanium nitride (TiN), or a combination thereof. The bias conductive line 303b may electrically connect the contact region 110 and the circuit included in the single photon avalanche diode layer 1. For example, the vertical connection 304 may be provided between the contact region 110 and the bias conductive line 303b and between the bias conductive line 303b and the circuit. The bias conductive line 303b may be configured to apply a bias to the single photon avalanche diode layer 1.

The lens unit 400 may be provided on the connection layer 300. The lens unit 400 may be provided on the opposite side of the single photon avalanche diode layer 1 with the connection layer 300 interposed therebetween. The lens unit 400 may include a lens 402. The lens 402 may focus incident light and transmit it to the single photon avalanche diode layer 1. For example, the lens 402 may include a microlens, a Fresnel lens, or a metalens. However, a type of the lens 402 is not limited and may be determined as needed. In example embodiments, a central axis of the lens 402 may be aligned with a central axis of the single photon avalanche diode layer 1. The central axis of the lens 402 and the central axis of the single photon avalanche diode layer 1 may pass through the center of the lens 402 and the center of the single photon avalanche diode layer 1, respectively. The central axis of the lens 402 and the central axis of the single photon avalanche diode layer 1 may be a virtual axis parallel to a stacking direction (i.e., the third direction D3) of the lens 402 and the single photon avalanche diode layer 1. In example embodiments, the central axis of lens 402 may be misaligned with the central axis of the single photon avalanche diode layer 1. In example embodiments, a width of the lens 402 may be approximately half a width of the single photon avalanche diode layer 1. In example embodiments, the lens 402 may be arranged in a 2×2 array. In example embodiments, at least one optical element may be inserted between the lens 402 and the single photon avalanche diode layer 1. For example, the optical elements include a color filter, a bandpass filter, a metal grid, an air grid, a grid based on a low refractive index material, an anti-reflective coating, a 2D nanomaterial layer, or an organic material layer. In example embodiments, the anti-reflective coating may be formed on a top of the lens 402.

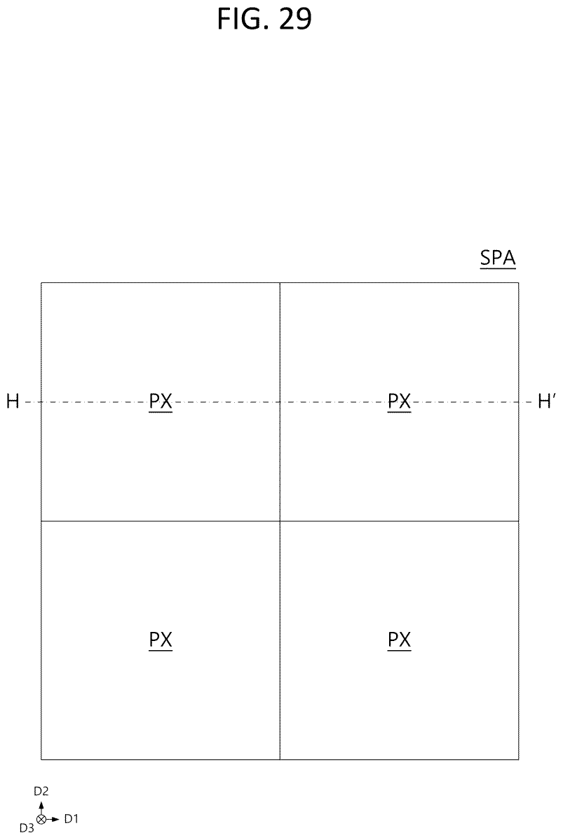

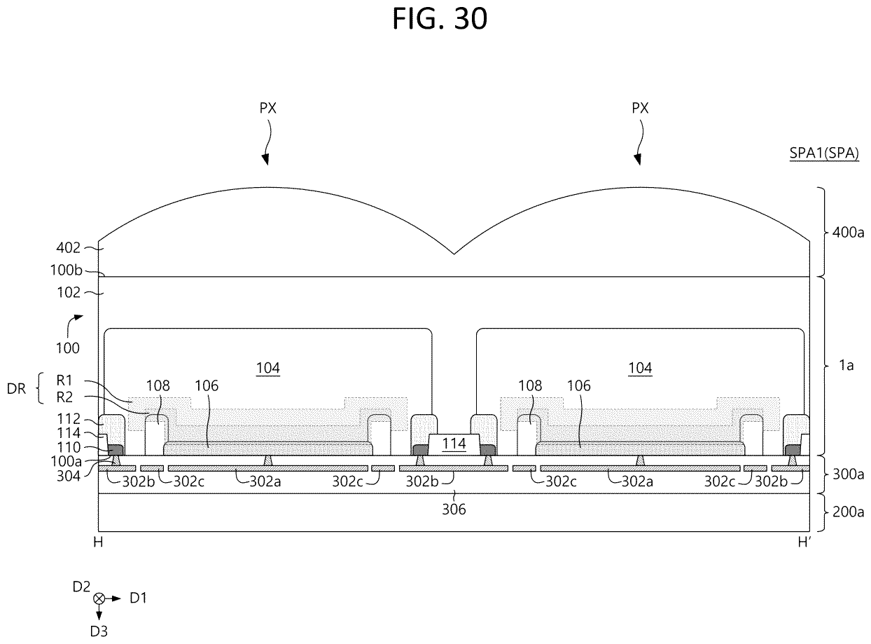

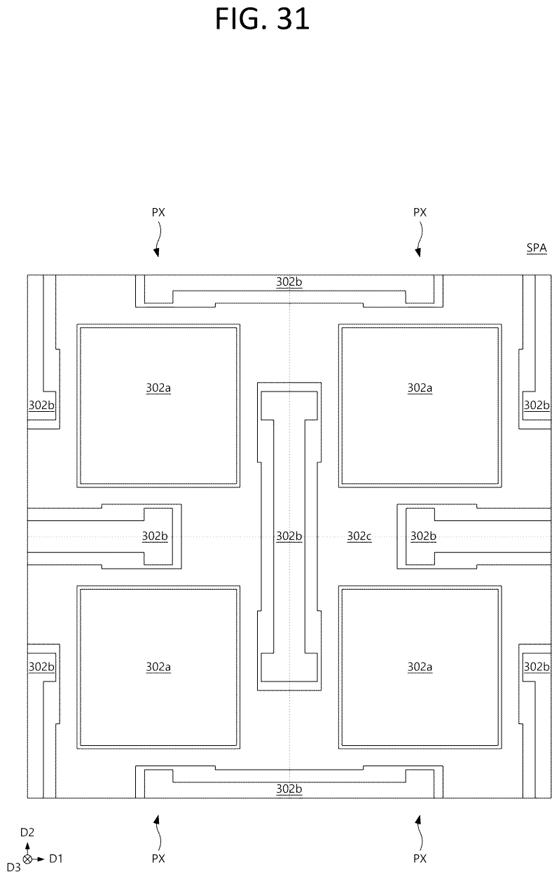

FIG. 29 is a plan view of a single photon detector array according to example embodiments. FIG. 30 is a cross-sectional view corresponding to line H-H′ of FIG. 29. FIG. 31 is a plan view of the output pattern, the bias pattern, and the shield pattern of FIG. 29. For brevity of explanation, content substantially the same as that described with reference to FIG. 23 may not be described.

Referring to FIGS. 29 to 31, a single photon detector array SPA1(SPA) may be provided. The single photon detector array SPA1(SPA) may include pixels PX arranged in two dimensions. Each of the pixels PX may include the single photon detector SPD1 described with reference to FIG. 23. The substrate regions 102, the control layers 200, the connection layers 300, and the lens units 400 of the pixels PX may be connected to each other. The single photon avalanche diode layers 1 of the single photon detectors SPD1 may be connected to form a single photon avalanche diode layer 1a of the single photon detector array SPA1(SPA). The connection layers 300 of the single photon detectors SPD1 may be connected to form a connection layer 300a of the single photon detector array SPA1(SPA). The control layers 200 of the single photon detectors SPD1 may be connected to form a control layer 200a of the single photon detector array SPA1(SPA). The lens units 400 of the single photon detectors SPD1 may be connected to form a lens unit 400a of the single photon detector array SPA1(SPA). In example embodiments, at least one optical element may be inserted between the lens 402 and the single photon avalanche diode layer 1a. For example, the optical elements include a color filter, a bandpass filter, a metal grid, an air grid, a grid based on a low refractive index material, an anti-reflective coating, a 2D nanomaterial layer, or an organic material layer. In example embodiments, the anti-reflective coating may be formed on a top of the lens 402.

The connection layer 300 may include an output pattern 302a, a bias pattern 302b, and a shield pattern 302c. The output pattern 302a, the bias pattern 302b, and the shield pattern 302c may serve as a reflective layer. Light that is not absorbed in the single photon avalanche diode layer 1a is reflected by the output pattern 302a, the bias pattern 302b, and the shield pattern 302c, and light is returned to the single photon avalanche diode layer 1a. Accordingly, the light absorption efficiency of the single photon avalanche diode layer 1a can be improved.

A pair of the contact regions 110 each included in the different pixels PX and immediately adjacent to each other may be configured to share the one bias pattern 302b. For example, the one bias pattern 302b and the pair of the contact regions 110 may be electrically connected to each other by a pair of vertical connections 304. A device isolation pattern 114 may be disposed between the pixels PX that are immediately adjacent to each other. For example, the device isolation pattern 114 may be shallow trench isolation (STI). For example, the vertical connection 304 may include a contact or a via.

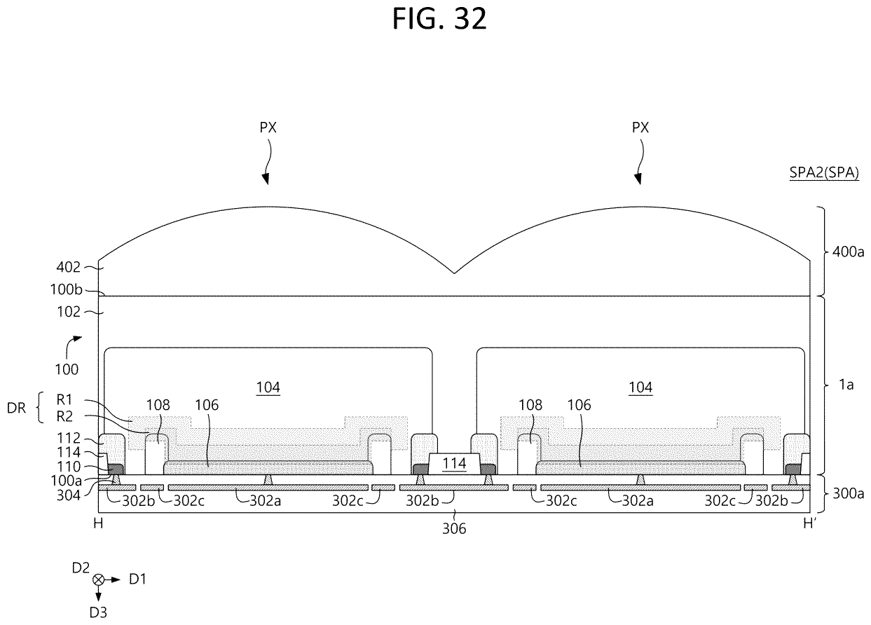

FIG. 32 is a cross-sectional view corresponding to line H-H′ of FIG. 29. For brevity of explanation, content substantially the same as that described with reference to FIG. 24 and that described with reference to FIGS. 29 to 31 may not be described.

Referring to FIGS. 29 and 32, a single photon detector array SPA2(SPA) may be provided. The single photon detector array SPA2(SPA) may include pixels PX arranged in two dimensions. Each of the pixels PX may include the single photon detector SPD2 described with reference to FIG. 24. The substrate regions 102, the connection layers 300, and the lens units 400 of the single photon detectors SPD2 may be connected to each other. The single photon avalanche diode layers 1 of the single photon detectors SPD2 may be connected to form a single photon avalanche diode layer 1a of the single photon detector array SPA2(SPA). The connection layers 300 of the single photon detectors SPD2 may be connected to form a connection layer 300a of the single photon detector array SPA2(SPA). The connection layer 300a may be substantially the same as the connection layer 300a described with reference to FIGS. 29 to 31. The lens units 400 of the single photon detectors SPD2 may be connected to form a lens unit 400a of the single photon detector array SPA2(SPA). The lens unit 400a may be substantially the same as the lens unit 400a described with reference to FIGS. 29 to 31.

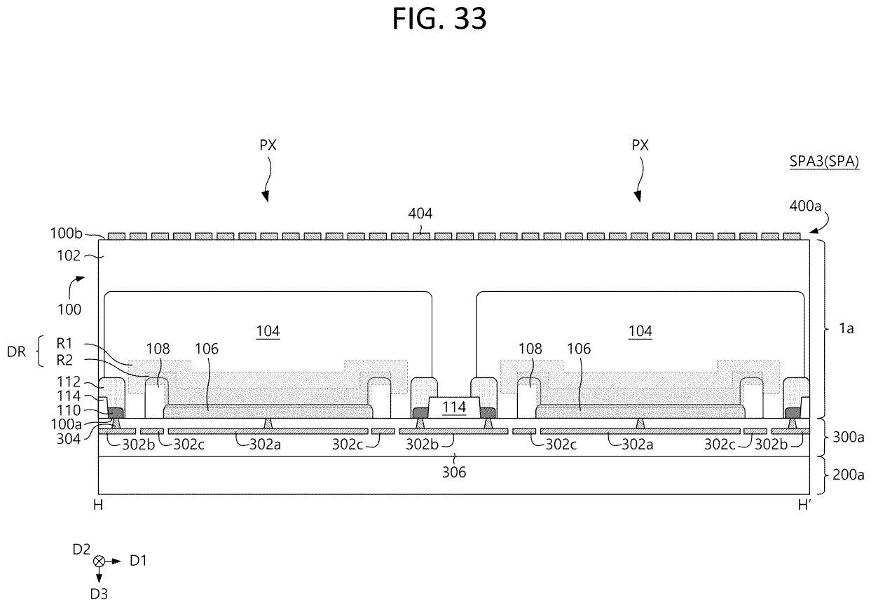

FIG. 33 is a cross-sectional view corresponding to line H-H′ of FIG. 29. For brevity of explanation, content substantially the same as that described with reference to FIGS. 25 and 26 may not be described.

Referring to FIGS. 29 and 33, a single photon detector array SPA3(SPA) may be provided. The single photon detector array SPA3(SPA) may include pixels PX arranged in two dimensions. Each of the pixels PX may include the single photon detector SPD3 described with reference to FIGS. 25 and 26. The substrate regions 102, the connection layers 300, and the lens units 400 of the single photon detectors SPD3 may be connected to each other. The single photon avalanche diode layers 1 of the single photon detectors SPD3 may be connected to form a single photon avalanche diode layer 1a of the single photon detector array SPA3(SPA). The connection layers 300 of the single photon detectors SPD3 may be connected to form a connection layer 300a of the single photon detector array SPA3(SPA). The control layers 200 of the single photon detectors SPD3 may be connected to form a control layer 200a of the single photon detector array SPA3(SPA). The lens units 400 of the single photon detectors SPD3 may be connected to form a lens unit 400a of the single photon detector array SPA3(SPA).

The lens unit 400a may include first diffraction patterns 404. The first diffraction patterns 404 may diffract incident light, thereby increasing the absorption length of light within the single photon avalanche diode layer 1a. In another example embodiments, scattering patterns may be provided on the back side 100b of the semiconductor substrate 100 instead of the first diffraction patterns 404. The scattering patterns may be, for example, cross or X-shaped patterns. In another example embodiments, the scattering patterns may be a combination of the cross and X-shaped patterns, or a connection of the cross and X-shaped patterns each other. The light absorption efficiency of the single photon avalanche diode layer 1a can be improved by the lens unit 400. In example embodiments, at least one optical element may be inserted between the first diffraction patterns 404 and the single photon avalanche diode layer 1a. For example, the optical elements include a color filter, a bandpass filter, a metal grid, an air grid, a grid based on a low refractive index material, an anti-reflective coating, a 2D nanomaterial layer, or an organic material layer.

The connection layer 300 may include an output pattern 302a, a bias pattern 302b, and a shield pattern 302c. The output pattern 302a, the bias pattern 302b, and the shield pattern 302c may serve as a reflective layer. Light that is not absorbed in the single photon avalanche diode layer 1a is reflected by the output pattern 302a, the bias pattern 302b, and the shield pattern 302c, and light is returned to the single photon avalanche diode layer 1a. Accordingly, the light absorption efficiency of the single photon avalanche diode layer 1a can be improved.

A pair of the contact regions 110 each included in the different pixels PX and immediately adjacent to each other may be configured to share the one bias pattern 302b. For example, the one bias pattern 302b and the pair of the contact regions 110 may be electrically connected to each other by a pair of vertical connections 304. A device isolation pattern 114 may be disposed between the pixels PX that are immediately adjacent to each other. For example, the device isolation pattern 114 may be shallow trench isolation (STI). For example, the pair of the vertical connections 304 may include contacts or vias.

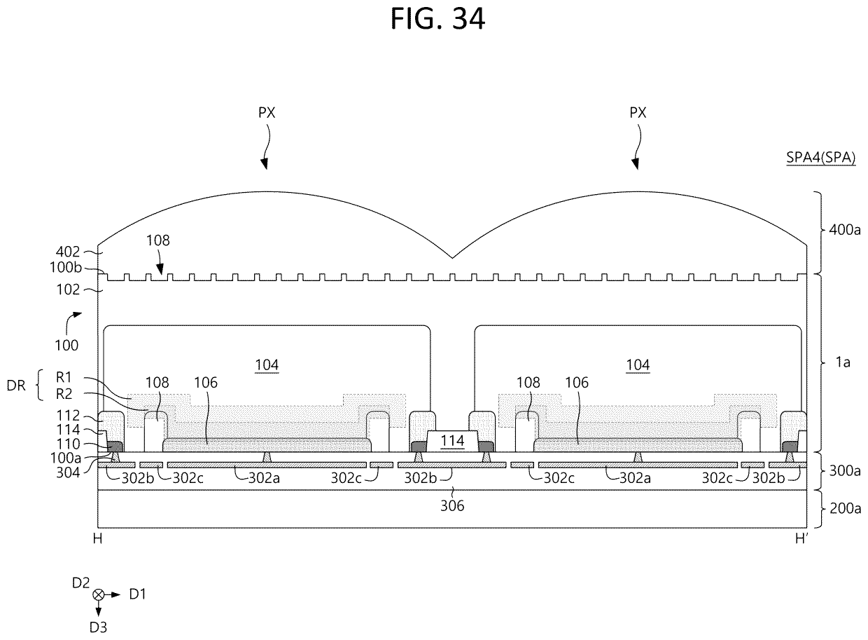

FIG. 34 is a cross-sectional view corresponding to line H-H′ of FIG. 29. For brevity of explanation, content substantially the same as that described with reference to FIG. 27 and that described with reference to FIGS. 29 to 31 may not be described.

Referring to FIGS. 29 and 34, a single photon detector array SPA4(SPA) may be provided. The single photon detector array SPA4(SPA) may include pixels PX arranged in two dimensions. Each of the pixels PX may include the single photon detector SPD4 described with reference to FIG. 27. The substrate regions 102, the control layers 200, the connection layers 300, and the lens units 400 of the pixels PX may be connected to each other. The single photon avalanche diodes 1 of the single photon detectors SPD4 may be connected to form a single photon avalanche diode layer 1a of the single photon detector array SPA4(SPA). The connection layers 300 of the single photon detectors SPD4 may be connected to form a connection layer 300a of the single photon detector array SPA4(SPA). The connection layer 300a may be substantially the same as the connection layer 300a described with reference to FIGS. 29 to 31. The control layers 200 of the single photon detectors SPD4 may be connected to form a control layer 200a of the single photon detector array SPA4(SPA).

Second diffraction patterns 109 may be provided on the back side 100b of the semiconductor substrate 100. For example, the second diffraction patterns 109 may be formed by etching the back side 100b of the semiconductor substrate 100. The second diffraction patterns 109 may diffract incident light and increase the absorption length of light within the single photon avalanche diode layer 1a. In another example embodiments, scattering patterns may be formed on the back side 100b of the semiconductor substrate 100 instead of the second diffraction patterns 109. The scattering patterns may be formed by etching the back side 100b of the semiconductor substrate 100. The scattering patterns may be, for example, cross or X-shaped patterns. In another example embodiments, the scattering patterns may be a combination of the cross and X-shaped patterns, or a connection of the cross and X-shaped patterns each other.

The lens units 400 of the single photon detectors SPD4 may be connected to form a lens unit 400a of the single photon detector array SPA4(SPA). The lens unit 400a may be substantially the same as the lens unit 400a described with reference to FIGS. 29 to 31.

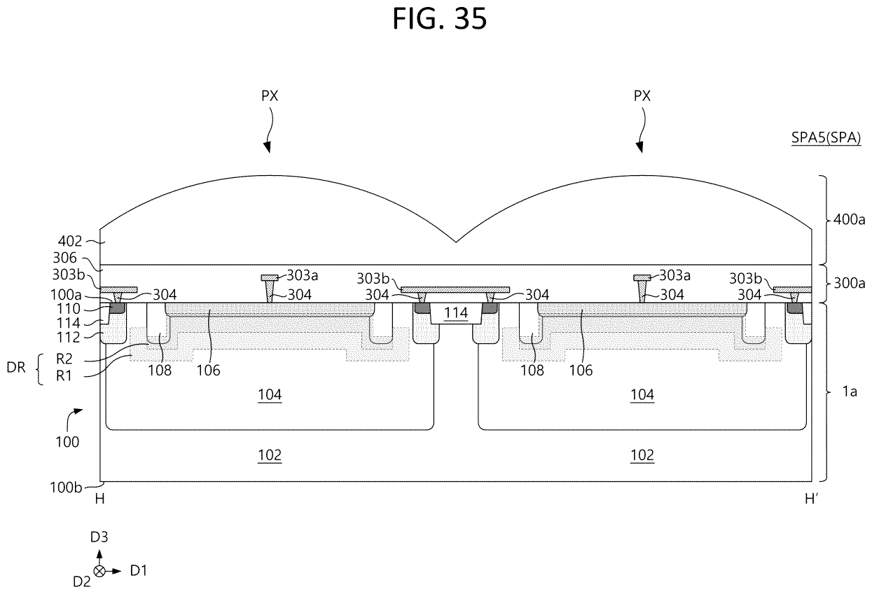

FIG. 35 is a cross-sectional view corresponding to line H-H′ of FIG. 29. For brevity of explanation, content substantially the same as that described with reference to FIG. 28 may not be described.

Referring to FIGS. 29 and 35, a single photon detector array SPA5(SPA) may be provided. The single photon detector array SPA5(SPA) may include pixels PX arranged in two dimensions. Each of the pixels PX may include the single photon detector SPD5 described with reference to FIG. 28. The substrate regions 102, the connection layers 300, and the lens units 400 of the single photon detectors SPD5 may be connected to each other. The single photon avalanche diodes 1 of the single photon detectors SPD5 may be connected to form a single photon avalanche diode layer 1a of the single photon detector array SPA5(SPA). The connection layers 300 of the single photon detectors SPD5 may be connected to form a connection layer 300a of the single photon detector array SPA5(SPA). The control layers 200 of the single photon detectors SPD5 may be connected to form a control layer 200a of the single photon detector array SPA5(SPA). The lens units 400 of the single photon detectors SPD5 may be connected to form a lens unit 400a of the single photon detector array SPA5(SPA). In example embodiments, at least one optical element may be inserted between lens 402 and the single photon avalanche diode layer 1a. For example, the optical elements include a color filter, a bandpass filter, a metal grid, an air grid, a grid based on a low refractive index material, an anti-reflective coating, a 2D nanomaterial layer, or an organic material layer. In example embodiments, the anti-reflective coating may be formed on a top of the lens 402.

The connection layer 300a may be provided on the front side 100a of the semiconductor substrate 100. The connection layer 300a may include an insulating layer 306, an output conductive line 303a, a bias conductive line 303b, and a vertical connection 304. The vertical connection 304 may include a contact or a via. For example, the insulating layer 306 may include silicon oxide (e.g., SiO₂), silicon nitride (e.g., SiN), silicon oxynitride (e.g., SiON), or a combination thereof. Since the single photon detector array SPA5(SPA) of the present disclosure may be configured to allow light to enter the front side 100a, incident light may sequentially pass through the lens unit 400a and the connection layer 300a, and reach the single photon avalanche diode layer 1a. Therefore, unlike the single photon detector arrays SPA1, SPA2, SPA3, SPA4 shown in FIGS. 30, 32, 33, and 34, incident light does not reach the single photon avalanche diode layer 1a. The output conductive line 303a and the bias conductive line 303b may be included instead of the output pattern 302a, the bias pattern 302b, and the shield pattern 302c so as not to prevent incident light from reaching the single photon avalanche diode layer 1a.

The output conductive line 303a may be electrically connected to the heavily doped region 106. The output conductive line 303a may include an electrically conductive material. For example, the output conductive line 303a may include copper (Cu), aluminum (Al), tungsten (W), titanium (Ti), titanium nitride (TiN), or a combination thereof. The output conductive line 303a may electrically connect the heavily doped region 106 and a circuit included in the single photon avalanche diode layer 1a. For example, a vertical connection 304 may be provided between the heavily doped region 106 and the output conductive line 303a and between the output conductive line 303a and the circuit. The output conductive line 303a may be configured to extract a detection signal from the single photon avalanche diode layer 1a.

The bias conductive line 303b may be electrically connected to the contact region 110. The bias conductive line 303b may include an electrically conductive material. For example, the bias conductive line 303b may include copper (Cu), aluminum (Al), tungsten (W), titanium (Ti), titanium nitride (TiN), or a combination thereof. The bias conductive line 303b may electrically connect the contact region 110 and the circuit included in the single photon avalanche diode layer 1a. For example, a vertical connection 304 may be provided between the contact region 110 and the bias conductive line 303b and between the bias conductive line 303b and the circuit. The bias conductive line 303b may be configured to apply a bias to the single photon avalanche diode layer 1a.

A pair of the contact regions 110 included in the different pixels PX and immediately adjacent to each other may be configured to share the one bias pattern 302b. For example, the one bias pattern 302b and the pair of the contact regions 110 may be electrically connected to each other by a pair of vertical connections 304. A device isolation pattern 114 may be disposed between the pixels PX that are immediately adjacent to each other. For example, the device isolation pattern 114 may be shallow trench isolation (STI). For example, the pair of the vertical connections 304 may include contacts or vias.

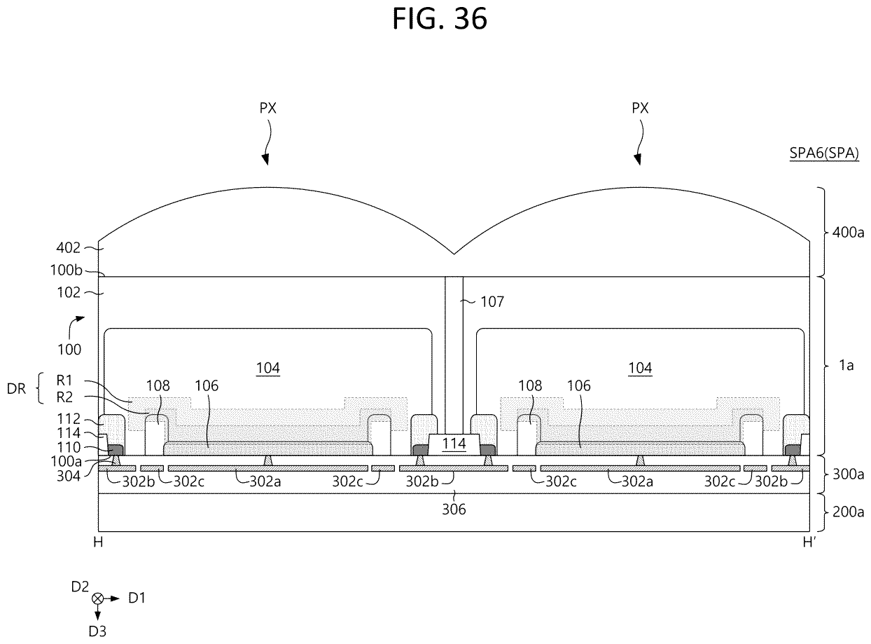

FIG. 36 is a cross-sectional view corresponding to line H-H′ of FIG. 29. For brevity of explanation, content substantially the same as that described with reference to FIG. 23 and that described with reference to FIGS. 29 to 31 may not be described.

Referring to FIGS. 29 and 36, a single photon detector array SPA6(SPA) may be provided. A device isolation pattern 114 may be disposed between pixels PX that are immediately adjacent to each other. For example, the device isolation pattern 114 may be shallow trench isolation (STI). A vertical separation pattern 107 may be provided between the device isolation pattern 114 and the back side 100b. For example, the vertical separation pattern 107 may be deep trench isolation (DTI). One end of the vertical isolation pattern 107 may directly contact the device isolation pattern 114, and the other end of the vertical isolation pattern 107 may be exposed on the back side 100b. For example, a top surface of the vertical separation pattern 107 may be located at substantially the same level as the back side 100b. The vertical separation pattern 107 may be formed by filling a recessed region formed by etching the substrate region 102 with a material that prevents crosstalk between the adjacent pixels PX. For example, the vertical separation pattern 107 may include metal (e.g., copper (Cu), aluminum (Al), tungsten (W), titanium (Ti)), polysilicon, high-k material (e.g., hafnium oxide (HfO₂), zirconium oxide (ZrO₂), tantalum oxide (TaO)), or a combination thereof.

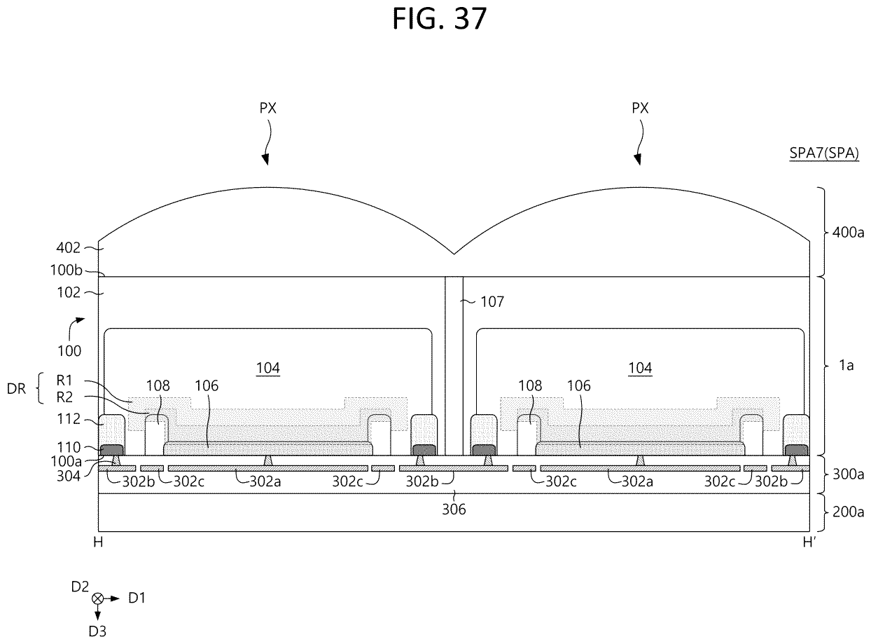

FIG. 37 is a cross-sectional view corresponding to line H-H′ of FIG. 29. For brevity of explanation, differences from those described with reference to FIG. 36 are described.

Referring to FIGS. 29 and 37, a single photon detector array SPA7(SPA) may be provided. Unlike the description with reference to FIG. 36, the single photon detector array SPA7(SPA) may include a vertical isolation pattern 107 that completely penetrates the semiconductor substrate 100 without the device isolation pattern 114. For example, the vertical separation pattern 107 may be deep trench isolation (DTI). One end of the vertical separation pattern 107 may be exposed on the front side 100a, and the other end of the vertical separation pattern 107 may be exposed on the back side 100b. For example, bottom and top surfaces of the vertical separation pattern 107 may be located at substantially the same level as the front and back sides 100a and 100b, respectively. For example, the vertical separation pattern 107 may be formed by filling a hole extending from the front side 100a to the back side 100b of the semiconductor substrate 100 with a material that prevents crosstalk between the adjacent pixels PX. For example, the vertical separation pattern 107 may include metal (e.g., copper (Cu), aluminum (Al), tungsten (W), titanium (Ti)), polysilicon, high-k material (e.g., hafnium oxide (HfO₂), zirconium oxide (ZrO₂), tantalum oxide (TaO)), or a combination thereof.

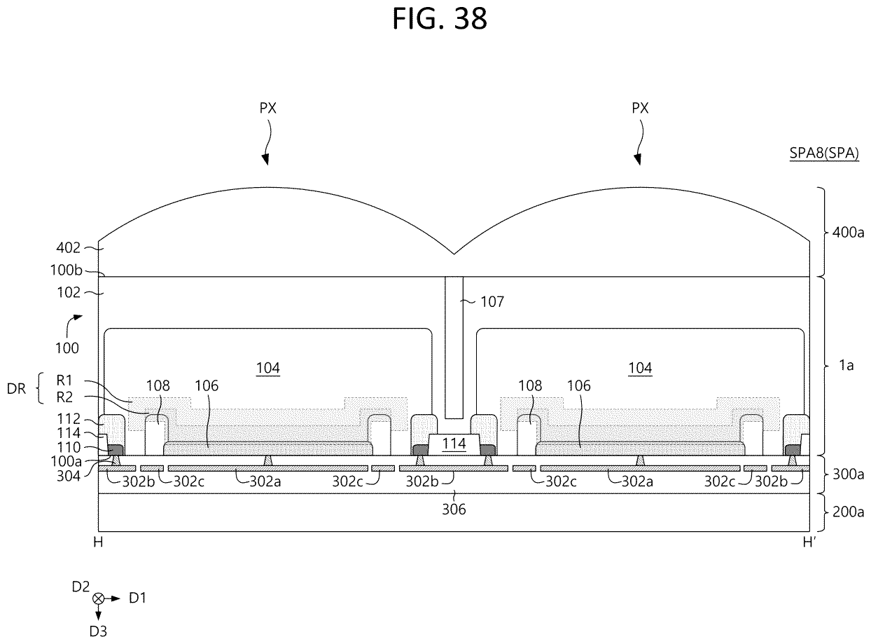

FIG. 38 is a cross-sectional view corresponding to line H-H′ of FIG. 29. For brevity of explanation, differences from those described with reference to FIG. 36 are described.

Referring to FIGS. 29 and 38, a single photon detector array SPA8(SPA) may be provided. Unlike the description with reference to FIG. 36, the device isolation pattern 114 and the vertical isolation pattern 107 may be spaced apart from each other. For example, the vertical separation pattern 107 may be deep trench isolation (DTI) or partial deep trench isolation (DTI). One end of the vertical isolation pattern 107 may be disposed adjacent to the device isolation pattern 114, and the other end of the vertical isolation pattern 107 may be exposed on the back side 100b. The substrate region 102 may be provided between the vertical isolation pattern 107 and the device isolation pattern 114. For example, a top surface of the vertical separation pattern 107 may be located at substantially the same level as the back side 100b. The vertical separation pattern 107 may be formed by filling a recessed region formed by etching the substrate region 102 with a material that prevents crosstalk between the adjacent pixels PX. For example, the vertical separation pattern 107 may include metal (e.g., copper (Cu), aluminum (Al), tungsten (W), titanium (Ti)), polysilicon, high-k material (e.g., hafnium oxide (HfO₂), zirconium oxide (ZrO₂), tantalum oxide (TaO)), or a combination thereof.

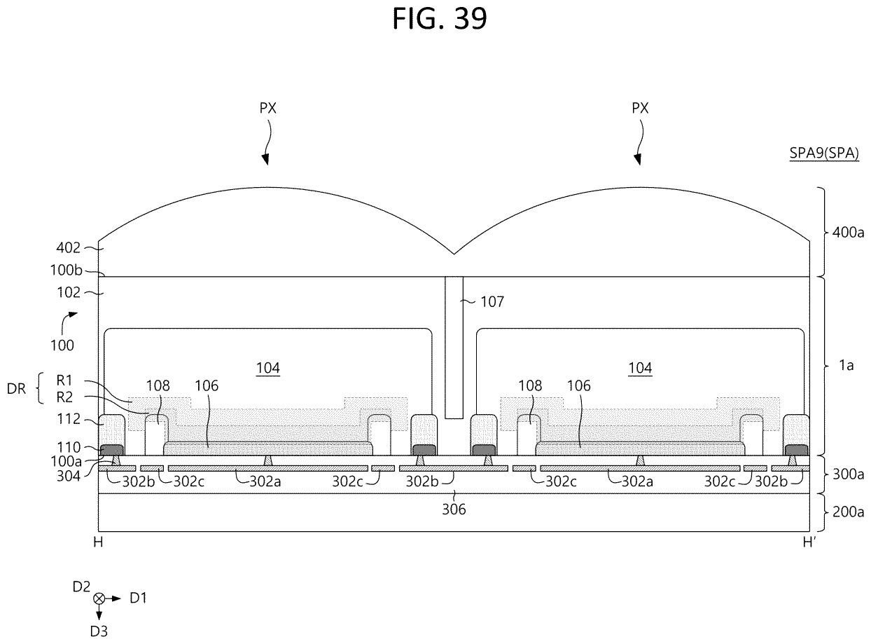

FIG. 39 is a cross-sectional view corresponding to line H-H′ of FIG. 29. For brevity of explanation, differences from those described with reference to FIG. 38 are described.

Referring to FIGS. 29 and 39, a single photon detector array SPA9(SPA) may be provided. Unlike the description with reference to FIG. 38, the single photon detector array SPA9(SPA) may include a vertical isolation pattern 107 that partially penetrates the semiconductor substrate 100 without the device isolation pattern 114. One end of the vertical separation pattern 107 may be disposed adjacent to the front side 100a of the semiconductor substrate 100, and the other end of the vertical separation pattern 107 may be exposed on the back side 100b. For example, a top surface of the vertical separation pattern 107 may be located at substantially the same level as the back side 100b. The vertical separation pattern 107 may be formed by filling a recessed region formed by etching the substrate region 102 with a material that prevents crosstalk between the adjacent pixels PX. For example, the vertical separation pattern 107 may include metal (e.g., copper (Cu), aluminum (Al), tungsten (W), titanium (Ti)), polysilicon, high-k material (e.g., hafnium oxide (HfO₂), zirconium oxide (ZrO₂), tantalum oxide (TaO)), or a combination thereof.

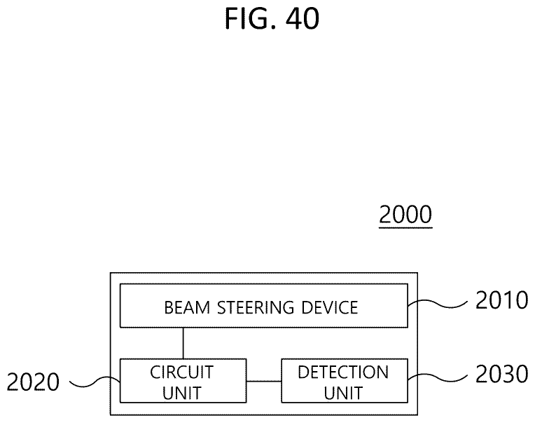

FIG. 40 is a block diagram for describing an electronic device according to example embodiments.

Referring to FIG. 40, an electronic device 2000 may be provided. The electronic device 2000 may radiate light toward a subject (not shown) and detect light reflected by the subject and returned to the electronic device 2000. The electronic device 2000 may include a beam steering device 2010. The beam steering device 2010 may adjust a direction of irradiation of light emitted to the outside of the electronic device 2000. The beam steering device 2010 may be a mechanical or a non-mechanical (semiconductor) beam steering device. The electronic device 2000 may include a light source unit within the beam steering device 2010 or may include the light source unit provided separately from the beam steering device 2010. The beam steering device 2010 may be a scanning type light emitting device. However, the light emitting device of the electronic device 2000 is not limited to the beam steering device 2010. In another example embodiments, the electronic device 2000 may include a flash-type light emitting device instead of the beam steering device 2010 or together with the beam steering device 2010. The flash-type light-emitting device may radiate light to a region including an entire field of view at once without a scanning process.

The light steered by the beam steering device 2010 may return to the electronic device 2000 after being reflected by the subject. The electronic device 2000 may include a detection unit 2030 for detecting light reflected by the subject. The detection unit 2030 may include a plurality of light detection elements and may further include other optical elements. A plurality of light detection elements may include any one of the single photon avalanche diodes 1000 to 1080 described above. In addition, the electronic device 2000 may further include a circuit unit 2020 connected to at least one of the beam steering device 2010 and the detection unit 2030. The circuit unit 2020 may include a calculation unit that acquires and calculates data, and may further include a driving unit and a control unit. In addition, the circuit unit 2020 may further include a power supply unit and a memory.

Although the case where the electronic device 2000 includes the beam steering device 2010 and the detection unit 2030 in one device is shown, the beam steering device 2010 and the detection unit 2030 are not provided as a single device. The beam steering device 2010 and the detection unit 2030 may be provided in separate devices. In addition, the circuit unit 2020 may be connected to the beam steering device 2010 or the detection unit 2030 through wireless communication without being wired.

The electronic device 2000 according to the embodiment described above may be applied to various electronic devices. For example, the electronic device 2000 may be applied to a Light Detection And Ranging (LiDAR) device. The LiDAR device may be a phase-shift or time-of-flight (TOF) type device. In addition, the single photon avalanche diodes 1000 to 1080 according to the embodiment or the electronic device 2000 including the same may be used in smartphones, wearable devices (glass-type devices realizing augmented reality and virtual reality, etc.), and the Internet of Things (IoTs) devices, home appliances, tablet Personal Computers (PCs), Personal Digital Assistants (PDAs), Portable Multimedia Player (PMPs), navigation, drones, robots, unmanned vehicles, self-driving cars, and Advanced Drivers Assistance System (ADAS).

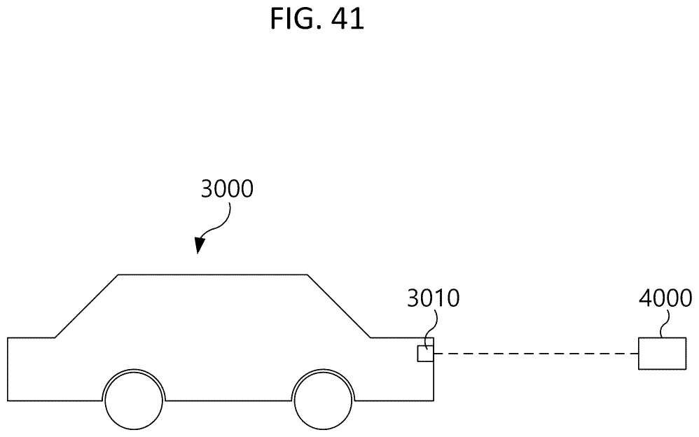

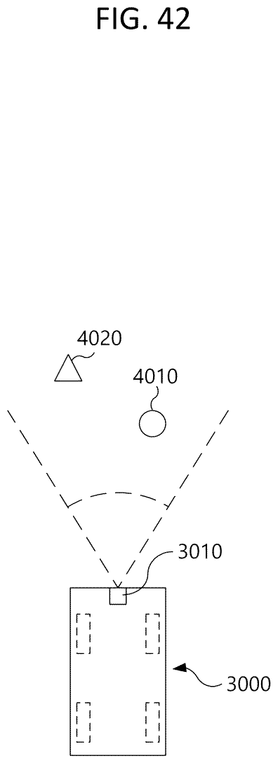

FIGS. 41 and 42 are conceptual diagrams illustrating cases in which a LiDAR device according to example embodiments is applied to a vehicle.

Referring to FIGS. 41 and 42, a LiDAR device 3010 may be applied to a vehicle 3000. Information on the subject 4000 may be obtained using the LiDAR device 3010 applied to a vehicle 3000. The vehicle 3000 may be an automobile having an autonomous driving function. The LiDAR device 3010 may detect an object or person (i.e., the subject 4000) in a direction in which the vehicle 3000 travels. The LiDAR device 3010 may measure the distance to the subject 4000 using information such as a time difference between a transmission signal and a detection signal. The LiDAR device 3010 may obtain information about a near subject 4010 and a far subject 4020 within a scanning range. The LiDAR device 3010 may include the electronic device 2000 described with reference to FIG. 40. Although the LiDAR device 3010 is disposed in front of the vehicle 3000 and detects the subject 4000 in the direction in which the vehicle 3000 travels, this is not limited. In another example embodiments, the LiDAR device 3010 may be disposed on the roof of the vehicle 3000 and rotates to detect all subjects around the vehicle 3000 at a plurality of locations on the vehicle 3000 so as to detect all subjects 4000 around the vehicle 3000. For example, four LiDAR devices 3010 may be placed at the front side, back side, and both sides of the vehicle 3000, respectively. In another example, the LiDAR device 3010 may be placed on the roof of the vehicle 3000, rotate, and detect all subjects 4000 around the vehicle 3000.

The above description of embodiments of the technical idea of the present disclosure provides examples for explanation of the technical idea of the present disclosure. Therefore, the technical idea of the present disclosure is not limited to the above embodiments, and it is clear that many modifications and changes, such as combining and implementing the above embodiments, are possible by those skilled in the art within the technical idea of the present disclosure.

What is claimed is:

1. A single photon avalanche diode comprising:
a first well having a first conductivity type;
a heavily doped region provided on the first well;
a guard ring surrounding the heavily doped region; and
a second region formed between the first well and the heavily doped region and configured to multiply charge carriers,
wherein the heavily doped region and the guard ring have a second conductivity type different from the first conductivity type, and
wherein the second region extends onto a boundary between a lower portion of the guard ring and the first well.

2. The single photon avalanche diode of claim 1, wherein, from a plan view, the second region overlaps the guard ring.

3. The single photon avalanche diode of claim 1, wherein the second region has an electric field of 3×10⁵ V/cm or more.

4. The single photon avalanche diode of claim 1, further comprising:
a first region formed between the first well and the second region and configured to transport the charge carriers to the second region,
wherein the first region has an electric field less than 3×10⁵ V/cm.

5. The single photon avalanche diode of claim 4, wherein the first region extends along a side of the guard ring disposed opposite the heavily doped region.

6. The single photon avalanche diode of claim 5, further comprising:
a relief region surrounding the guard ring; and
a contact region provided on the relief region,
wherein the first region extends between the relief region and the guard ring.

7. The single photon avalanche diode of claim 6, further comprising:
a device isolation pattern surrounding the relief region.

8. The single photon avalanche diode of claim 1, wherein the second region extends onto a bottom surface of the guard ring.

9. The single photon avalanche diode of claim 1, further comprising:
a contact region surrounding the guard ring; and
a first insulating pattern provided between the contact region and the guard ring.

10. The single photon avalanche diode of claim 1, further comprising:
a second insulating pattern provided on the guard ring.

11. The single photon avalanche diode of claim 1, further comprising:
a lightly doped region provided between the heavily doped region and the guard ring and between the heavily doped region and the first well,
wherein the lightly doped region has the second conductivity type and a lower doping concentration than a doping concentration of the heavily doped region.

12. The single photon avalanche diode of claim 1, further comprising:
a second well provided between the heavily doped region and the first well,
wherein the second well has a different conductivity type and a different doping concentration with the first well.

13. The single photon avalanche diode of claim 12, wherein the second region extends along boundaries between the second well and the heavily doped region and between the second well and the guard ring.

14. The single photon avalanche diode of claim 1, further comprising:
a third well provided between the heavily doped region and the first well,
wherein the third well has the second conductivity type, and
wherein the doping concentration of the third well is lower than a doping concentration of the heavily doped region, but higher than a doping concentration of the guard ring.

15. The single photon avalanche diode of claim 14, wherein the second region extends along a boundary between the first well and the third well.

16. The single photon avalanche diode of claim 1, further comprising:
a virtual guard ring formed between the guard ring and the first well,
wherein the virtual guard ring is configured to alleviate a concentration of electric field in the second region.

17. An electronic device comprising a single photon avalanche diode, wherein the single photon avalanche diode includes:
a first well having a first conductivity type;
a heavily doped region provided on the first well;
a guard ring surrounding the heavily doped region; and
a second region formed between the first well and the heavily doped region and configured to multiply charge carriers,
wherein the heavily doped region and the guard ring have a second conductivity type different from the first conductivity type, and
wherein the second region extends onto a boundary between a lower portion of the guard ring and the first well.

18. The electronic device of claim 17, further comprising:
a first region formed between the first well and the second region and configured to transport the charge carriers to the second region.

19. A LiDAR device comprising:
an electronic device including a single photon avalanche diode,
wherein the single photon avalanche diode includes:
a first well having a first conductivity type;
a heavily doped region provided on the first well;
a guard ring surrounding the heavily doped region; and
a second region formed between the first well and the heavily doped region and configured to multiply charge carriers,
wherein the heavily doped region and the guard ring have a second conductivity type different from the first conductivity type, and
wherein the second region extends onto an interface between a lower portion of the guard ring and the first well.

20. The LiDAR device of claim 19, further comprising:
a first region formed between the first well and the second region and configured to transport the charge carriers to the second region.
